(19) United States
(12) Patent Application Publication
(10) Pub. No.: US 2026/0333575 A1
(43) Pub. Date: Oct. 22, 2026

(54) ELECTRONIC DEVICE

(71) Applicant: DENSO CORPORATION, Kariya-city (JP)

(72) Inventors: Noboru NAGASE, Kariya-city (JP); Yusuke MASUMOTO, Kariya-city (JP); Jun FUKUHARA, Kariya-city (JP)

(21) Appl. No.: 19/692,537

(22) Filed: May 29, 2026

Related U.S. Application Data
(63) Continuation of application No. PCT/JP2025/001255, filed on Jan. 17, 2025.

(30) Foreign Application Priority Data
Jan. 23, 2024 (JP) 2024-008245

(51) Int. Cl. H05K 1/02; H05K 1/181; H10W 74/10; H10W 90/00

(52) U.S. Cl. CPC H05K 1/0271; H05K 1/181; H10W 74/114; H10W 90/796; H05K 2201/09063; H05K 2201/09136

(57) ABSTRACT

An electronic device includes a printed circuit board, a semiconductor package, and a case. The case has a portion facing the first surface of the printed circuit board. The printed circuit board has a fixing hole for fixing to the case. A warping direction of the printed circuit board and a warping direction of the semiconductor package during temperature fluctuation are opposite to each other. The printed circuit board has a stress relief portion configured to relieve stress acting on a mounting section of the semiconductor package.

### CROSS REFERENCE TO RELATED APPLICATION

The present application is a continuation application of International Patent Application No. PCT/JP2025/001255 filed on Jan. 17, 2025, which designated the U.S. and claims the benefit of priority from Japanese Patent Application No. 2024-008245 filed on Jan. 23, 2024. The entire disclosures of all of the above applications are incorporated herein by reference.

### TECHNICAL FIELD

The present disclosure relates to an electronic device.

### BACKGROUND

An electronic device includes a printed circuit board, a semiconductor package mounted on the printed circuit board, and a fixed structure. The printed circuit board has a through hole, and is fixed to the fixed structure by screw fastening. The contents of JP 2014-212240 A are incorporated herein by reference to explain technical elements in this description.

### SUMMARY

An electronic device includes: a printed circuit board having a first surface and a second surface opposite to each other in a thickness direction; a semiconductor package mounted on the printed circuit board; and a fixed structure having a portion opposing the first surface. The printed circuit board has a fixing hole to fix the printed circuit board to the fixed structure. A warping direction of the printed circuit board and a warping direction of the semiconductor package, during temperature fluctuation, are opposite to each other in the thickness direction. The printed circuit board may have a stress relief portion to relieve stress on a mounting portion of the semiconductor package due to difference in warping direction.

### BRIEF DESCRIPTION OF DRAWINGS

FIG. 1 is a cross-sectional view illustrating an electronic device according to a first embodiment.

FIG. 2 is a plan view illustrating a printed circuit board of the electronic device.

FIG. 3 is a plan view illustrating another example of the printed circuit board.

FIG. 4 is a cross-sectional view taken along line IV-IV in FIG. 2.

FIG. 5 is a cross-sectional view illustrating a semiconductor package.

FIG. 6 is a diagram illustrating warping of a semiconductor package.

FIG. 7 is a diagram illustrating a reference example.

FIG. 8 is a diagram illustrating a reference example.

FIG. 9 is a diagram illustrating a reference example.

FIG. 10 is a diagram illustrating a reference example.

FIG. 11 is a diagram illustrating warping characteristics of a printed circuit board when the warping direction is different.

FIG. 12 is a diagram showing warping characteristics of a printed circuit board when the warping direction is the same.

FIG. 13 is a diagram illustrating a modification.

FIG. 14 is a diagram illustrating a modification.

FIG. 15 is a diagram illustrating a modification.

FIG. 16 is a diagram illustrating a modification.

FIG. 17 is a cross-sectional view illustrating a semiconductor package of an electronic device according to a second embodiment.

FIG. 18 is a diagram illustrating a reference example.

FIG. 19 is a diagram illustrating a reference example.

FIG. 20 is a diagram illustrating a reference example.

FIG. 21 is a diagram illustrating a reference example.

FIG. 22 is a diagram illustrating a reference example.

FIG. 23 is a diagram illustrating a reference example.

FIG. 24 is a diagram illustrating a reference example.

FIG. 25 is a diagram illustrating a reference example.

FIG. 26 is a diagram illustrating a reference example.

FIG. 27 is a cross-sectional view illustrating an electronic device.

FIG. 28 is a diagram illustrating a modification.

FIG. 29 is a cross-sectional view illustrating a semiconductor package of an electronic device according to a third embodiment.

FIG. 30 is a cross-sectional view illustrating an electronic device.

FIG. 31 is a cross-sectional view illustrating another example of the electronic device.

FIG. 32 is a cross-sectional view illustrating an electronic device according to a fourth embodiment.

FIG. 33 is a cross-sectional view illustrating a part of a printed circuit board of an electronic device according to a fifth embodiment.

FIG. 34 is a plan view illustrating a printed circuit board of an electronic device according to a sixth embodiment.

FIG. 35 is a diagram illustrating a modification.

### DETAILED DESCRIPTION

An electronic device includes a printed circuit board, a semiconductor package mounted on the printed circuit board, and a fixed structure. The printed circuit board has a through hole, and is fixed to the fixed structure by screw in the through hole.

A slit is provided between the through hole and the semiconductor package to reduce distortion that occurs around the through hole due to screw fastening, thereby ensuring connection reliability for the semiconductor package located near the through hole. However, depending on the mounting position of the semiconductor package, there are cases where the connection reliability can be ensured without providing a slit, when the printed circuit board and the semiconductor package have a common configuration. Even if the semiconductor package is mounted at a position away from the through hole, the connection reliability may be reduced. In terms of the above perspectives, or other perspectives not mentioned, further improvements are awaited for electronic devices.

The present disclosure provides an electronic device to improve connection reliability of a semiconductor package.

According to an aspect of the disclosure, an electronic device includes: a printed circuit board having a first surface and a second surface opposite to each other in a thickness direction; a semiconductor package mounted on the printed circuit board; and a fixed structure having a portion opposing the first surface. The printed circuit board has fixing holes for fixing the printed circuit board to the fixed structure. A warping direction of the printed circuit board and a warping direction of the semiconductor package, during temperature fluctuation, are opposite to each other along the thickness direction. The printed circuit board has a stress relief portion to relieve stress acting on a mounting portion of the semiconductor package due to difference in warping direction.

When the warping direction of the semiconductor package, during temperature fluctuation, is opposite to the warping direction of the printed circuit board, stress is concentrated at the mounting portion of the semiconductor package, such that the connection reliability is reduced. According to the electronic device having the stress relief portion, it is possible to relax the stress acting on the mounting portion of the semiconductor package due to difference in warping direction. Therefore, the connection reliability of the semiconductor package can be improved.

The multiple embodiments disclosed in this description employ different technical means to achieve their respective objectives. The objects, features, and advantages disclosed in this specification will become apparent by referring to following detailed descriptions and accompanying drawings.

Hereinafter, embodiments are described with reference to the drawings. Duplicate description may be omitted by assigning the same reference numerals to the corresponding elements in each embodiment. In cases where only a part of the configuration is described in each embodiment, the configurations of other portions previously described in other embodiments may be applied to those parts. Furthermore, in the descriptions of each embodiment, not only the explicitly stated combinations of configurations, but also, as long as there is no particular hindrance to their combination, configurations from multiple embodiments may be partially combined with each other, even if such combinations are not explicitly described.

### First Embodiment

A schematic configuration of an electronic device will be described. The electronic device may be mounted on, for example, a mobile object. Examples of the mobile object include a vehicle, a flying object, a ship, a construction machine, and an agricultural machine. The electronic device of the present embodiment is mounted on a vehicle, for example.

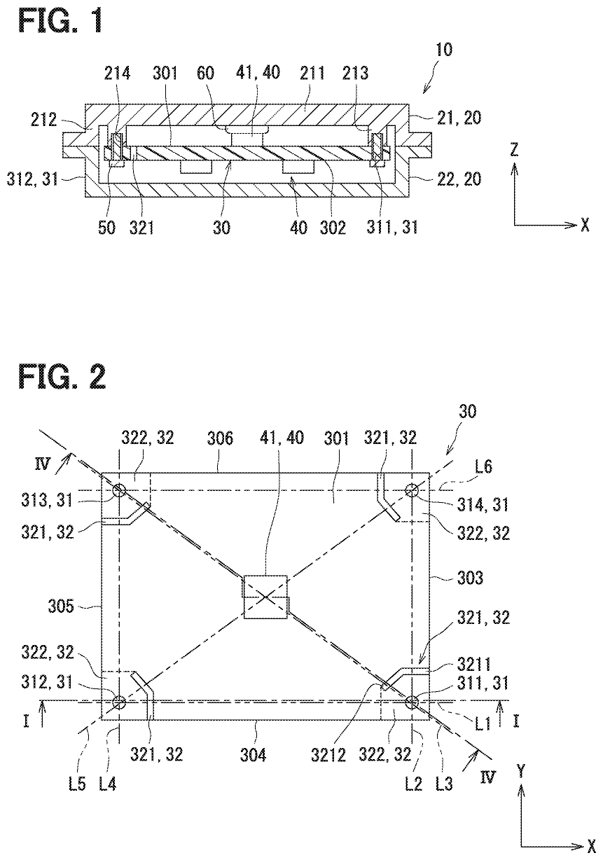

FIG. 1 is a cross-sectional view showing an electronic device taken along line I-I in FIG. 2. In the following description, the thickness direction of the printed circuit board is referred to as Z direction. A direction perpendicular to the Z direction is referred to as X direction, and a direction perpendicular to both of the Z direction and the X direction is referred to as Y direction. As long as otherwise specified, a shape viewed in a plane from the Z direction, that is, a shape along an XY plane defined by the X direction and Y direction is referred to as a planar shape. The planar view seen in the Z direction may be simply referred to as a plan view.

As shown in FIG. 1, the electronic device 10 includes a housing 20, a printed circuit board 30, and an electronic component 40. The electronic device 10 of this embodiment further includes a screw 50 and a heat dissipation gel 60. The electronic device 10 may further include a connector (not shown). The connector is mounted on the printed circuit board 30 to electrically connect the circuit formed by the printed circuit board 30 and the electronic component 40 to the outside of the electronic device 10 (external equipment).

The housing 20 forms the outer shell of the electronic device 10. The housing 20 houses the other elements that make up the electronic device 10. The housing 20 may be formed using a metal material such as Al or Fe, or may be formed using a resin material such as PPS or PBT. The housing 20 may be formed using ceramic. For example, a part of the housing 20 may be made of a metal material, and another part may be made of a resin material. The planar shape of the housing 20 is, for example, substantially rectangular.

The housing 20 of this embodiment includes a case 21 and a cover 22. The case 21 and the cover 22 are made of Al. The case 21 is box-shaped with one side open in the Z direction. The case 21 has an opposing wall 211, a side wall 212, plural pedestals 213, and a screw hole 214. The opposing wall 211 faces a first surface 301 of the printed circuit board 30. The side wall 212 is continuous with the opposing wall 211. The side wall 212 extends in the Z direction from the opposing wall 211.

The pedestal 213 protrudes from the opposing wall 211 and supports the printed circuit board 30. The pedestal 213 may be provided apart from the side wall 212 or may be provided in a manner that is continuous with the side wall 212. The case 21 has four pedestals 213 to support the four corners of the printed circuit board 30. The screw hole 214 is provided in each of the pedestals 213. The case 21 corresponds to a fixed structure.

The cover 22 is attached to the case 21. In the assembled state, the cover 22 provides a storage space together with the case 21. The cover 22 is provided to close the opening of the case 21. The cover 22 is fixed to the case 21 by screws or the like.

The printed circuit board 30 may be referred to as substrate, wiring board, or printed wiring board. The printed circuit board 30 has the first surface 301 and a second surface 302. The second surface 302 is opposite to the first surface 301 in the Z direction, which is the thickness direction of the printed circuit board 30. A planar shape of the printed circuit board 30 is not particularly limited. As an example, the printed circuit board 30 of the present embodiment has a substantially rectangular planar shape.

The printed circuit board 30 includes an insulating base member and a conductor. The insulating base member is made of a material having an electrical insulating property, such as resin. As the insulating base material, for example, a material containing only resin may be employed, or a material containing resin in combination with glass cloth, nonwoven fabric, etc. may be employed. The conductor is made of a metal material having a reliable electrical conductivity, such as copper. The conductor includes a wiring layer. The wiring layer may be referred to as a wiring, a wiring pattern, a conductor pattern, or the like. The wiring layer may be formed by patterning metal foil, for example, or may be formed by printing. At least some of the conductors, together with the electronic component 40, form a circuit. The printed circuit board 30 on which the electronic component 40 is mounted is called a circuit board.

The wiring includes at least surface wiring arranged on the surface of the substrate adjacent to the first surface 301. The wiring may include surface wiring arranged on the surface layer adjacent to the second surface 302, or/and an inner layer wiring arranged inside the base material. That is, the printed circuit board 30 may be a single-layer board, a double-sided board, or a multi-layer board. The printed circuit board 30 of this embodiment is a glass epoxy board in which multiple wiring layers are arranged. The printed circuit board 30 has lands, which are electrode portions of wiring layers, on the surface layers of the first surface 301 and the second surface 302.

The conductor may include a via conductor or a through-hole land in addition to the wiring layer. The via conductor is a conductor, such as plating, in a through-hole (via) formed in the insulating layer of the insulating base member. The via conductor electrically connects the wiring layers arranged in different layers. The through-hole land is formed on a wall surface of a through-hole that penetrates the printed circuit board 30 in the Z direction. The conductor may include a heat dissipation conductor that does not provide a wiring function.

The printed circuit board 30 has fixing holes 31. The fixing hole 31 penetrates the printed circuit board 30 in the Z direction. The fixing holes 31 are used for fixing the printed circuit board 30 to the case 21. The fixing holes 31 are respectively provided at the four corners of the printed circuit board 30. The fixing holes 31 are provided to overlap the screw holes 214 in a plan view. The fixing hole 31 may be referred to as mounting hole. The screw 50 is inserted into the fixing hole 31. The screw 50 is inserted through the fixing hole 31 and is screwed into the screw hole 214 of the pedestal 213. The printed circuit board 30 is fixed to the case 21 (housing 20) by screw fastening.

The electronic component 40 is mounted on the printed circuit board 30. The electronic component 40, together with the conductors of the printed circuit board 30, provide a circuit. The electronic components 40 are soldered to the corresponding lands. The electronic component 40 includes at least a surface-mount semiconductor package 41. The semiconductor package 41 is sometimes called an IC package. The electronic component 40 may include only the semiconductor package 41, or may include other components in addition to the semiconductor package 41. The electronic components 40 may be arranged on only the first surface 301 or only the second surface 302. The electronic components 40 may be arranged on both the first surface 301 and the second surface 302.

The electronic device 10 of this embodiment includes plural electronic components 40. The electronic components 40 are arranged on both the first surface 301 and the second surface 302. The semiconductor package 41 is arranged on the first surface 301. The heat dissipation gel 60 is in close contact with the semiconductor package 41. The heat dissipation gel 60 is interposed between the semiconductor package 41 and the inner surface of the opposing wall 211 of the case 21. This allows heat generated by the semiconductor package 41 to be released to the case 21 (housing 20) via the heat dissipation gel 60. The arrangement of the semiconductor packages 41 is not limited to the example shown in FIG. 1. The semiconductor package 41 may be disposed on the second surface 302 or may be disposed on both the first surface 301 and the second surface 302.

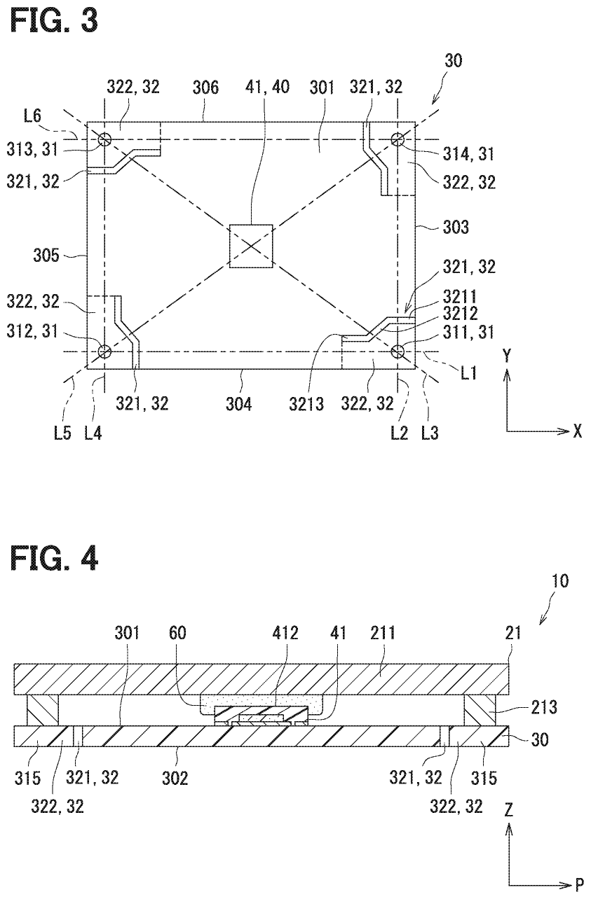

Next, the structure of the printed circuit board will be described in more detail with reference to FIGS. 2 to 4. FIG. 2 is a plan view showing a printed circuit board. FIG. 3 is a plan view showing another example of a printed circuit board. FIGS. 2 and 3 show a semiconductor package mounted on a printed circuit board. FIG. 4 is a cross-sectional view taken along line IV-IV of FIG. 2. For convenience, FIG. 4 shows only the case, which is a fixed structure, of the housing. Also, the case is shown in a simplified manner. As the electronic component, only a semiconductor package is shown. The P direction shown in FIG. 4 is a predetermined direction along the line IV-IV.

As shown in FIGS. 2 and 3, the printed circuit board 30 has a generally rectangular shape in a plan view with the X direction as the longitudinal direction and the Y direction as the lateral direction. The printed circuit board 30 has side surfaces 303, 304, 305, 306 that connect the first surface 301 and the second surface 302. The side surface 304 is opposite to the side surface 303 in the X direction. The side surface 306 is opposite to the side surface 305 in the Y direction.

The printed circuit board 30 has the plural fixing holes 31 as described above. The fixing hole 31 is provided around each of the four corners of the printed circuit board 30, which has a substantially rectangular shape in a plan view. The printed circuit board 30 has four fixing holes 311, 312, 313, 314 as the fixing hole 31. The fixing hole 311 is provided at a corner defined by the two side surfaces 303 and 304. The fixing hole 312 is provided at the corner defined by the two side surfaces 304 and 305. The fixing hole 313 is provided at the corner defined by the two side surfaces 305 and 306. The fixing hole 314 is provided at the corner defined by the two side surfaces 306 and 303.

In the following description, a portion of the printed circuit board 30 that is fixed to the case 21 by the screw 50, that is, the fixing hole 31 and its surrounding area, may be referred to as a fixing portion 315. The fixing portion 315 overlaps with the head of the screw 50 in a plan view. For convenience, FIG. 4 omits the screw hole 214, the fixing hole 31, and the screw 50, and only shows the fixing portion 315. One of the fixing portions 315 shown in FIG. 4 corresponds to the fixing hole 311, and the other corresponds to the fixing hole 313.

The printed circuit board 30 further includes a stress relief portion 32. The stress relief portion 32 relieves stress acting on the mounting portion (solder joint portion) of the semiconductor package 41 when the warping direction of the semiconductor package 41 and the warping direction of the printed circuit board 30 are different (opposite directions), as will be described later. As an example, the stress relief portion 32 of this embodiment includes a slit 321 and a partition portion 322.

The slit 321 penetrates the printed circuit board 30 in the Z direction and extends in a predetermined direction within the XY plane. The slit 321 blocks the transmission of stress originating from the fixing hole 31 (fixing portion 315). The slit 321 defines a portion of the printed circuit board 30 that includes the fixing hole 31 (fixing portion 315). The slits 321 are provided in correspondence with the fixing holes 31. The slit 321 is provided for each of the fixing holes 31. The slit 321 is provided near the four corners of the printed circuit board 30. The slit 321 is arranged to cross at least one of imaginary straight lines L1, L2, L3, L4, L5, L6 that virtually connect the centers of the fixing holes 31 in a plan view. In FIGS. 2 and 3, the imaginary straight line is indicated by a two-dot chain line.

The imaginary straight line L1 imaginarily connects the fixing holes 311 and 312. The imaginary straight line L2 imaginarily connects the fixing holes 311 and 314. The imaginary straight line L3 imaginarily connects the fixing holes 311 and 313. The imaginary straight line L4 imaginarily connects the fixing holes 312 and 313. The imaginary straight line L5 imaginarily connects the fixing holes 312 and 314. The imaginary straight line L6 imaginarily connects the fixing holes 313 and 314.

In this embodiment, at least one slit 321 crosses all of the imaginary straight lines L1, L2, L3, L4, L5, L6. Each of the slits 321 is arranged to cross two imaginary straight lines. The slit 321 is open in the side surface of the printed circuit board 30. The slit 321 is open in a first side surface of the printed circuit board 30, which has a generally rectangular shape in a plan view, and extends from the first side surface toward a second side surface opposite the first side surface. All the slits 321 have a common shape in a plan view.

Specifically, the slit 321 corresponding to the fixing hole 311 is open in the side surface 303, extends toward the side surface 305, and crosses the imaginary straight line L2, L3. The slit 321 corresponding to the fixing hole 312 is open in the side surface 304, extends toward the side surface 306, and crosses the imaginary straight line L1 , L5. The slit 321 corresponding to the fixing hole 312 is located by rotating by 90° clockwise around an axis substantially parallel to the Z direction relative to the slit 321 corresponding to the fixing hole 311. The slit 321 corresponding to the fixing hole 313 is open in the side surface 305, extends toward the side surface 303, and crosses the imaginary straight line L3, L4. The slit 321 corresponding to the fixing hole 313 is arranged rotated by 90° clockwise around an axis substantially parallel to the Z direction relative to the slit 321 corresponding to the fixing hole 312. The slit 321 corresponding to the fixing hole 314 is open in the side surface 306, extends toward the side surface 304, and crosses the imaginary straight line L5, L6. The slit 321 corresponding to the fixing hole 314 is located by rotating by 90° clockwise around an axis substantially parallel to the Z direction relative to the slit 321 corresponding to the fixing hole 313. The slits 321 have rotational symmetry.

The shape and extension length of the slit 321 are not particularly limited. In FIGS. 2 and 3, each of the slits 321 crosses two imaginary straight lines. The stress relief portion 32 may employ either the slit 321 shown in FIG. 2 or FIG. 3. The slit 321 shown in FIG. 2 has a first slit portion 3211 and a second slit portion 3212. The first slit portion 3211 has one end open in the side surface and extends in a direction perpendicular to the side surface. The second slit portion 3212 is connected to the end portion opposite to the open end of the first slit portion 3211 and extends obliquely to narrow the width of the partition portion 322. For example, the first slit portion 3211 of the slit 321 corresponding to the fixing hole 311 extends in the X direction, and the second slit portion 3212 extends in an oblique direction to approach the side surface 304.

The slit 321 shown in FIG. 3 is longer than the slit 321 shown in FIG. 2. The slit 321 shown in FIG. 3 has a third slit portion 3213 in addition to the first slit portion 3211 and the second slit portion 3212. The first slit portion 3211 and the second slit portion 3212 have the same configuration as that shown in FIG. 2. The third slit portion 3213 is continuous with the end of the second slit portion 3212 opposite to the first slit portion 3211, and extends approximately parallel to the first slit portion 3211. For example, the third slit portion 3213 of the slit 321 corresponding to the fixing hole 311 extends in the X direction.

The partition portion 322 is a part of the printed circuit board 30 partitioned by the slit 321, and includes the fixing hole 31 (fixing portion 315). The partition portion 322 is an area located inside the slit 321. The end of the partition portion 322 is defined by the slit 321. The dashed line shown in FIGS. 2 and 3 indicates the end of the partition portion 322. The partition portion 322 extends generally in the X direction or the Y direction. The partition portion 322 is provided to be capable of elastic deformation (spring deformation). The partition portion 322 relieves stress originating from the fixing hole 31 (fixing portion 315) by deformation.

The partition portion 322 including the fixing hole 311 extends in the X direction from the fixing hole 311 (fixing portion 315). The partition portion 322 including the fixing hole 312 extends from the fixing hole 312 in the Y direction. The partition portion 322 including the fixing hole 313 extends from the fixing hole 313 in the X direction. The partition portion 322 including the fixing hole 314 extends from the fixing hole 314 in the Y direction.

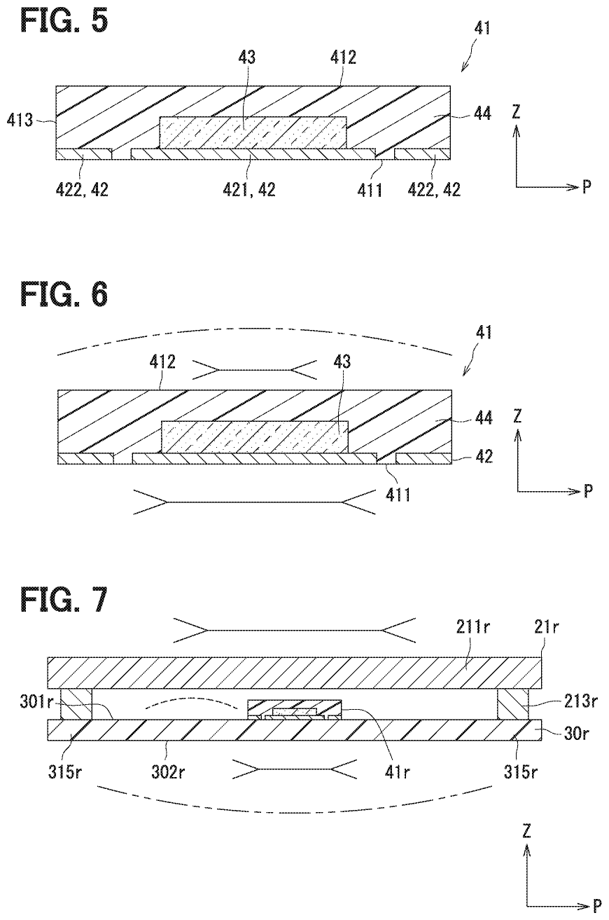

Next, the structure of the semiconductor package will be described in more detail with reference to FIGS. 2 to 5. FIG. 5 is a cross-sectional view showing an example of a semiconductor package. FIG. 5 is a cross-sectional view corresponding to FIG. 4.

In the semiconductor package 41, leads may protrude from the main body, or may not protrude as a non-leaded package. The semiconductor package 41 of this embodiment is a non-leaded package as shown in FIG. 5. As the non-leaded package, QFN, SON, BGA, etc. can be adopted. QFN is an abbreviation for Quad Flat Non-leaded package. SON is an abbreviation for Small Outline Non-leaded package. BGA is an abbreviation for Ball Grid Array. The semiconductor package 41 of this embodiment is a QFN.

The semiconductor package 41 has a lower surface 411, an upper surface 412, and a side surface 413 as surfaces that form the outer shell. The lower surface 411 faces the printed circuit board 30. The lower surface 411 may be referred to as a bottom surface, an opposing surface, or the like. The upper surface 412 is opposite to the lower surface 411 in the Z direction. The side surface 413 connects the lower surface 411 and the upper surface 412. In FIG. 4, the heat dissipation gel 60 is interposed between the upper surface 412 of the semiconductor package 41 and the inner surface of the opposing wall 211 of the case 21.

The semiconductor package 41 includes a lead frame 42, a semiconductor chip 43, and a sealing resin body 44. The lead frame 42 is a metal plate made of a metal material with good conductivity, such as Cu. The lead frame 42 of this embodiment is formed using Cu. The lead frame 42 may be referred to as a conductor, a metal plate, or the like. The lead frame 42 has an island 421 and plural terminals 422. The island 421 has the semiconductor chip 43 disposed thereon. The island 421 may be called a heat dissipation plate, a heat diffusion plate, a heat sink, or a heat dissipation pad. The island 421 is exposed from the lower surface 411 and is substantially flush with the lower surface 411. The island 421 is soldered to corresponding land on the printed circuit board 30. The lands may provide a circuit, or lands that do not provide a circuit function but provide a heat dissipation function.

The terminal 422 is soldered to corresponding land on the printed circuit board 30. The terminal 422 may be referred to as an electrode, an electrode pad, or the like. The terminal 422 is arranged to surround the island 421 in a plan view. The terminals 422 are respectively arranged along the four sides of the lower surface 411 which has a generally rectangular planar shape. The terminals 422 are exposed from the lower surface 411 and are substantially flush with the lower surface 411. Each of the terminals 422 is exposed from the side surface 413 and is substantially flush with the side surface 413. The terminals 422 are exposed from the four side surfaces 413.

The semiconductor chip 43 is formed by forming elements and integrated circuits on a semiconductor substrate. The semiconductor chip 43 of this embodiment has an integrated circuit formed on a semiconductor substrate made of Si. The semiconductor chip 43 is disposed on one surface of the island 421 and bonded to the island 421. The one surface is opposite to the exposed surface. The semiconductor chip 43 has pads (not shown) on the surface opposite to the island 421. The pads of the semiconductor chip 43 are electrically connected to the terminals 422 via conductive members (not shown) such as bonding wires.

The sealing resin body 44 seals the semiconductor chip 43. The sealing resin body 44 is in contact with the top and side surfaces of the semiconductor chip 43. The sealing resin body 44 forms the outer shell of the semiconductor package 41. Each of the island 421 and the terminal 422 is sealed with the sealing resin body 44. The sealing resin body 44 may be called a mold resin, a sealing body, or the like.

Next, warp of a semiconductor package will be described with reference to FIG. 6. FIG. 6 shows warp amount and shape when the temperature is decreased. The solid line with inward arrows at both ends indicates the magnitude (amount) of shrinkage (warp). The two-dot chain line indicates the warp shape of the semiconductor package when the temperature drops. FIG. 6 corresponds to FIG. 5.

The semiconductor package 41 warps during temperature fluctuation due to difference in the linear expansion coefficients of its components. In the semiconductor package 41 shown in FIG. 5, the linear expansion coefficient of Cu constituting the lead frame 42 is approximately 16 ppm/°C, and the linear expansion coefficient of Si constituting the semiconductor chip 43 is approximately 3 ppm/°C. Therefore, when the temperature drops, the lead frame 42 shrinks significantly in a direction perpendicular to the Z direction. On the other hand, the amount of shrinkage of the semiconductor chip 43 is small. Therefore, as shown by the two-dot chain line in FIG. 6, the outer periphery of the semiconductor package 41 is warped downward, which is defined as cry warp.

The strength of the sealing resin body 44 is weaker than that of Cu or Si. The linear expansion coefficient of the sealing resin body 44 is selected to be approximately the intermediate value between Cu and Si, for example, 8 to 14 ppm/°C, to be close to the linear expansion coefficient of the printed circuit board 30. Therefore, the sealing resin body 44 cannot eliminate the cry warp. When the temperature drops, the semiconductor package 41 undergoes the cry warping.

Here, the example is for when the temperature is decreasing, but the same applies when the temperature is increasing. Due to the difference in linear expansion coefficient, the lead frame 42 expands significantly when the temperature rises. On the other hand, the semiconductor chip 43 expands less. As a result, the outer periphery is warped upward, which is defined as smile warp.

Next, warp of a printed circuit board will be described with reference to FIGS. 7 to 10. Also, the influence of the relationship between the warp of the printed circuit board and the warp of the semiconductor package on the mounting portion of the semiconductor package will be described. FIGS. 7 to 10 show reference examples. The reference example differs from this embodiment in that no stress relief portion such as a slit is provided in the printed circuit board. In the reference example, a character “r” is added to the end of the reference numerals of related elements in the present embodiment. FIGS. 7 to 10 correspond to FIG. 4. For convenience, the heat dissipation gel is omitted. As in FIG. 6, the solid line with inward arrows at both ends indicates the magnitude (amount) of contraction. The two-dot chain line indicates the warp shape of the printed circuit board when the temperature drops. The dashed line indicates the warp shape of the semiconductor package when the temperature drops.

In the reference example shown in FIG. 7, a case 21r, which is a fixed structure, is made of Al. The linear expansion coefficient of Al that constitutes the case 21r is 21 to 23 ppm/°C, and the linear expansion coefficient of the printed circuit board 30r is approximately 14 ppm/°C. Therefore, when the temperature drops with the printed circuit board 30r fixed to the case 21r, the case 21r (opposing wall 211r) shrinks significantly in the direction perpendicular to the Z direction. On the other hand, the amount of shrinkage of the printed circuit board 30r is small. As a result, the outer periphery of the printed circuit board 30r is warped upward, which is defined smile warp.

The semiconductor package 41r is disposed on the first surface 301r of the printed circuit board 30r. The semiconductor package 41r has the same configuration as the semiconductor package 41 shown in FIG. 5. Therefore, when the temperature drops, the semiconductor package 41r develops a cry warp as shown by the dashed line. Therefore, the warp shape of the printed circuit board 30r is forced to the cry warp shape when reaching the portion where the semiconductor package 41r is mounted.

In this way, due to the difference in linear expansion coefficients between the case 21r and the printed circuit board 30r, when the warping direction of the printed circuit board 30r and the warping direction of the semiconductor package 41r are opposite to each other along the Z direction, a sudden deformation stress is applied to the mounting portion (solder joint portion) of the semiconductor package 41r. Specifically, the case 21r contracts due to a temperature drop, and a displacement is applied between the fixing portions 315r (fixing holes) of the printed circuit board 30r, causing deformation in a direction to shorten the distance between the fixing portions 315r. The stress caused by this deformation acts on the semiconductor package 41r from the fixing portion 315r (fixing hole). In environments where temperature changes are large and there are many cooling and heating cycles, such as in in-vehicle products, the connection reliability of the mounting portion is likely to decrease. In other words, the solder life is likely to be reduced.

When the temperature rises, the case 21r expands more than the printed circuit board 30r, causing a cry warp in the printed circuit board 30r. As described above, a smile warp occurs in the semiconductor package 41r. The semiconductor package 41r is disposed on the first surface 301r, and the warping direction is reversed. Therefore, the connection reliability of the mounting portion of the semiconductor package 41r is likely to decrease.

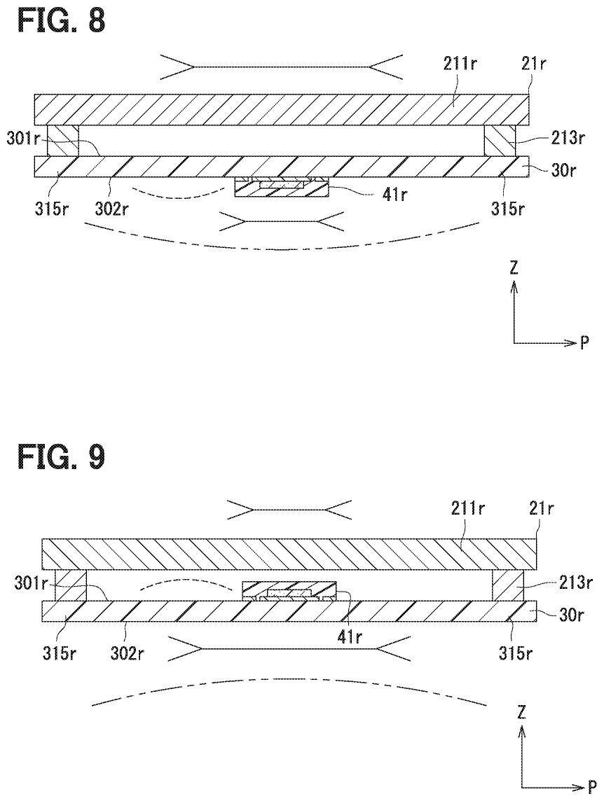

In the reference example shown in FIG. 8, the semiconductor package 41r is disposed on the second surface 302r of the printed circuit board 30r. The other configurations are the same as those of the reference example shown in FIG. 7. When the temperature drops, a smile warp occurs in the printed circuit board 30r due to the difference in the linear expansion coefficient between the case 21r and the printed circuit board 30r.

When the temperature drops, the semiconductor package 41r develops a cry warp as shown by the dashed line. However, the semiconductor package 41r is disposed on the second surface 302r. Therefore, the warping direction of the printed circuit board 30r and the warping direction of the semiconductor package 41r are the same (common direction). Therefore, it is possible to prevent sudden deformation stress from being applied to the mounting portion (solder joint portion) of the semiconductor package 41r.

When the temperature rises, the printed circuit board 30r undergoes the cry warping. A smile warp occurs in the semiconductor package 41r. The semiconductor package 41r is disposed on the second surface 302r, and the warping direction is the same. Therefore, it is possible to prevent sudden deformation stress from being applied to the mounting portion of the semiconductor package 41r.

In the reference example shown in FIG. 9, the case 21r, which is a fixed structure, is made of Fe. The linear expansion coefficient of Fe that constitutes the case 21r is 10 to 12 ppm/°C, which is smaller than the linear expansion coefficient of the printed circuit board 30r (approximately 14 ppm/°C). When the temperature drops, the printed circuit board 30r shrinks significantly in the direction perpendicular to the Z direction. On the other hand, the amount of shrinkage of the case 21r (opposing wall 211r) is small. As a result, the outer periphery of the printed circuit board 30r is warped downward, that is, the cry warp occurs.

When the temperature drops, the semiconductor package 41r develops a cry warp as shown by the dashed line. The semiconductor package 41r is disposed on the first surface 301r of the printed circuit board 30r, as in FIG. 7. Therefore, the warping direction of the printed circuit board 30r and the warping direction of the semiconductor package 41r are the same. Therefore, it is possible to prevent sudden deformation stress from being applied to the mounting portion (solder joint portion) of the semiconductor package 41r.

When the temperature rises, smile warp occurs in the printed circuit board 30r, and smile warp occurs in the semiconductor package 41r. The semiconductor package 41r is arranged on the first surface 301r, and the warping direction is the same. Therefore, it is possible to prevent sudden deformation stress from being applied to the mounting portion of the semiconductor package 41r.

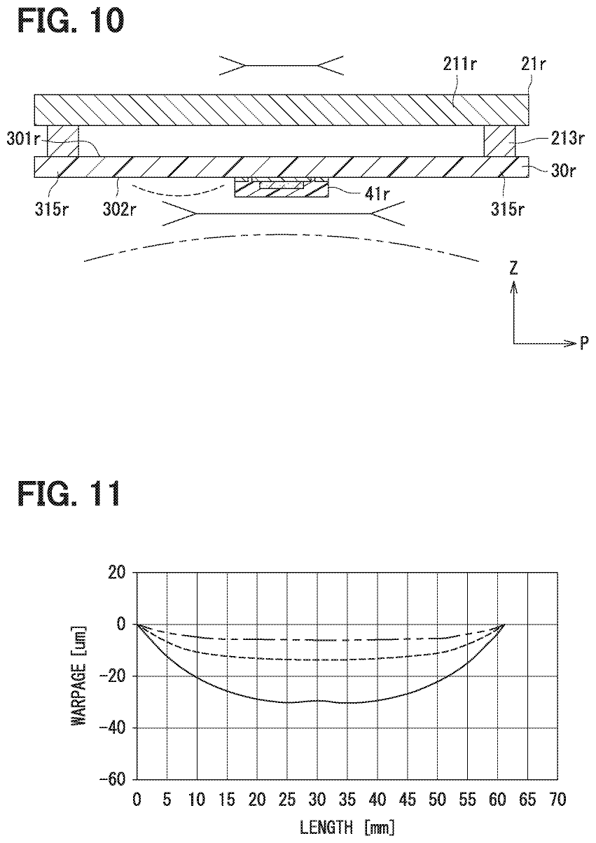

In the reference example shown in FIG. 10, the semiconductor package 41r is disposed on the second surface 302r of the printed circuit board 30r. The other configurations are the same as those of the reference example shown in FIG. 9. When the temperature drops, the difference in the linear expansion coefficient between the case 21r and the printed circuit board 30r causes a cry warp in the printed circuit board 30r. When the temperature drops, the semiconductor package 41r develops a cry warp as shown by the dashed line. However, the semiconductor package 41r is disposed on the second surface 302r. Therefore, the warping direction of the printed circuit board 30r and the warping direction of the semiconductor package 41r are opposite to each other. Therefore, the connection reliability of the mounting portion of the semiconductor package 41r is likely to decrease.

When the temperature rises, the case 21r expands less than the printed circuit board 30r, causing a smile warp in the printed circuit board 30r. A smile warp occurs in the semiconductor package 41r. The semiconductor package 41r is disposed on the second surface 302r, and the warping direction is reversed. Therefore, the connection reliability of the mounting portion of the semiconductor package 41r is likely to decrease.

As described above, the connection reliability of the mounting portion of the semiconductor package 41r depends on the warp relationship between the printed circuit board 30r based on the difference in linear expansion coefficient with the fixed structure and the semiconductor package 41r based on the difference in linear expansion coefficient with the components. For example, when the warping direction is opposite, stress is concentrated at the mounting portion of the semiconductor package 41r, resulting in a decrease in connection reliability.

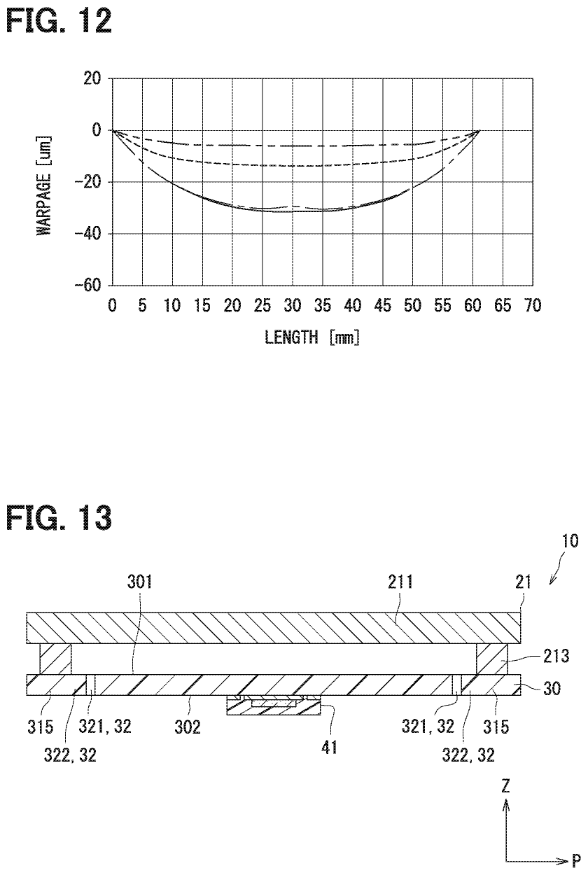

Next, the effect of the stress relief portion will be described with reference to FIGS. 11 and 12 showing the results of simulation. FIG. 11 shows the warp characteristics of a printed circuit board when the temperature is lowered from 20 °C to −40 °C in case where the warping direction of the printed circuit board and the warping direction of the semiconductor package are different.

As a configuration with different warping directions, a printed circuit board i fixed to a case (housing) made of Al and a semiconductor package is placed on the first surface of the printed circuit board, similarly to FIG. 7. Then, the amount of warp (variation in depth dimension) of the printed circuit board is sampled along the diagonal line of the printed circuit board. In FIG. 11, no slits (no stress relief portions) are indicated by solid lines, small slits by dashed lines, and large slits by double chain lines. The size of the slit indicates the length of the slit. The small slit corresponds to the configuration shown in FIG. 2. The large slit corresponds to the configuration shown in FIG. 3.

Since the case, which is a fixed structure, is made of Al, when the temperature drops, smile warp occurs in the printed circuit board due to the difference in linear expansion coefficient between the case and the printed circuit board. Furthermore, cry warp occurs in the semiconductor package. Since the semiconductor package is disposed on the first surface of the printed circuit board, the warping direction of the printed circuit board and the warping direction of the semiconductor package are opposite to each other. When no slits (no stress relief portions) are provided, the results shown by the solid line in FIG. 11 show that smile warp suddenly changes to cry warp, from the fixing holes (fixing portions). In other words, a sudden deformation stress is applied to the mounting portion (solder joint portion) of the semiconductor package, which is the boundary between the smile warp and the cry warp.

When a small slit is provided, the results shown by the dashed line in FIG. 11 show that the curve is abruptly inflected around the fixing hole, reducing the amount of warping, that is, alleviating stress. The printed circuit board becomes almost flat in the area closer to the center of the board than the slits. When a large slit is provided, the effect of the slit becomes more pronounced. The effect of stress relaxation and the effect of flattening the central region are further enhanced in the double chain line in FIG. 11.

FIG. 12 shows the warping characteristics of a printed circuit board when the temperature is decreased from 20 °C to −40 °C, with the warping direction being the same. As a configuration with the same warping direction, a printed circuit board is fixed to a case (housing) made of Al and a semiconductor package is placed on the second surface of the printed circuit board, similarly to FIG. 8. Then, the amount of warp of the printed circuit board is sampled along the diagonal line. In FIG. 12, no slits (no stress relief portions) are indicated by solid lines, small slits by dashed lines, and large slits by double chain lines. For comparison, the results without slits shown in FIG. 11 are indicated by a single chain line.

When the temperature drops, smile warp occurs in the printed circuit board due to the difference in the linear expansion coefficient between the case and the printed circuit board. Furthermore, cry warp occurs in the semiconductor package. Since the semiconductor package is disposed on the second surface of the printed circuit board, the warping of the printed circuit board and the warping of the semiconductor package are in the same direction. When no slits (no stress relief portions) are provided, the results shown by the solid line in FIG. 12 show that the mounting area of the semiconductor package does not deform into cry warp, but instead the entire area becomes smile warp. In other words, no sudden deformation stress is applied to the mounting portion (solder joint portion) of the semiconductor package. This point is also clear from a comparison between the solid line and the single chain line in FIG. 12.

When a small slit is provided, the results shown by the dashed line in FIG. 12 show that the curve is abruptly inflected around the fixing hole, reducing the amount of warping. The printed circuit board becomes almost flat in the area closer to the center of the board than the slits. When a large slit is provided, the results shown by the double chain line in FIG. 12 show that the effect of flattening the central region is further enhanced. The results for the small slit and the large slit are almost the same between FIG. 11 and FIG. 12.

According to the first embodiment, as shown in FIGS. 1 and 4, the linear expansion coefficient of the case 21, which is the fixed structure, is greater than the linear expansion coefficient of the printed circuit board 30. For example, when the temperature drops, the printed circuit board 30 develops a smile warp, similar to the configuration shown in FIG. 7. The semiconductor package 41 has the lead frame 42, the semiconductor chip 43 arranged on the lead frame 42, and the sealing resin body 44. Therefore, when the temperature drops, the semiconductor package 41 develops a cry warp as shown in FIG. 6. The semiconductor package 41 is disposed on the first surface 301 of the printed circuit board 30. When the temperature drops, the warping direction of the printed circuit board 30 and the warping direction of the semiconductor package 41 are opposite to each other.

For example, when the temperature rises, the printed circuit board 30 undergoes cry warping. The semiconductor package 41 has a smile warp. The semiconductor package 41 is arranged on the first surface 301, and the warping direction is reversed.

In this configuration in which the warping direction is reversed when the temperature changes, the printed circuit board 30 is provided with the stress relief portion 32. The stress relief portion 32 relieves stress acting on the mounting portion (solder joint portion) of the semiconductor package 41 due to different warping directions. Therefore, the connection reliability of the semiconductor package 41 can be improved.

As illustrated, the semiconductor package 41 may be a non-leaded package. In the case of non-lead package, since there are no leads protruding from the sealing resin body 44, stress relaxation due to elastic deformation of the leads cannot be achieved. Compared to packages with leads, the connection reliability is more likely to decrease due to the application of stress. In other words, the solder life is likely to be reduced. The connection reliability is likely to decrease in environments where there are large temperature changes and frequent cooling and heating cycles, such as in automotive products. By employing the non-lead semiconductor package 41 and providing the stress relief portion 32 in a configuration in which the warping direction is reversed, the connection reliability of the non-lead semiconductor package 41 can be improved. Furthermore, by using a non-leaded package, the size of the printed circuit board 30 and the electronic device 10 can be reduced.

The semiconductor package 41 may have leads protruding from the sealing resin body 44. The effect of the stress relief portion 32 is to relax part of the stress acting on the mounting portion of the semiconductor package 41 due to the different warping directions. Another part of the stress can be relieved by the lead being elastically deformed.

The stress relief portion 32 may be provided around the fixing hole 31 (fixing portion 315). By providing the stress relief portion 32 around the fixing hole 31 (fixing portion 315), which is the origin of the stress, it becomes easier to reduce the stress.

The stress relief portion 32 may include a portion that relieves stress by elastic deformation. By elastically deforming (spring deformation), the stress acting on the mounting portion of the semiconductor package 41 can be effectively alleviated.

The stress relief portion 32 may have the slit 321 and the partition portion 322 provided for each of the fixing holes 31. Since the slit 321 penetrates the printed circuit board 30, the slit 321 can block the transmission of stress. In other words, the range of stress transmission can be limited. The partition portion 322 defined by the slit 321 is elastically deformed when stress is applied. The elastic deformation of the partition portion 322 can relieve stress.

The slit 321 may be arranged to cross at least one of the imaginary straight lines L1, L2, L3, L4, L5, and L6 that virtually connect different fixing holes 31 together. Displacement occurs between the fixing holes 31 due to temperature fluctuations, and deformation stress acts with the fixing holes 31 as the starting point. Therefore, by arranging the slit 321 to cross the imaginary straight line, it is possible to suppress displacement between the fixing holes 31 and to alleviate the stress acting on the mounting portion of the semiconductor package 41.

Preferably, at least one slit 321 is arranged to cross all of the imaginary straight lines L1, L2, L3, L4, L5, and L6. Since the slit 321 is always located between the fixing holes 31, the stress acting on the mounting portion of the semiconductor package 41 can be effectively alleviated.

The slit 321 may be open in the side surface of the printed circuit board 30. By providing the slit 321 up to the edge of the printed circuit board 30 in this way, it is easy to limit the stress transmission range. Furthermore, the partition portion 322 and the mounting area are connected at one location, which makes it easier for the partition portion 322 to be elastically deformed.

In the printed circuit board 30 having a generally rectangular planar shape, the slit 321 may be open in the first side surface and extend from the first side surface toward a second side surface opposite the first side surface. This makes the partition portion 322 narrower and longer, making it easier to elastically deform. Therefore, the stress acting on the mounting portion of the semiconductor package 41 can be effectively alleviated.

### Modifications

The arrangement of the semiconductor packages 41 is not limited to the first surface 301. For example, as shown in FIG. 13, when the semiconductor package 41 is provided on the second surface 302, the stress relief portion 32 may be provided on the printed circuit board 30. In FIG. 13, the case 21 is made of Fe. Therefore, when the temperature drops, the printed circuit board 30 undergoes cry warping. Although the semiconductor package 41 undergoes the cry warping, since the semiconductor package 41 is disposed on the second surface 302, the warping direction of the printed circuit board 30 and the warping direction of the semiconductor package 41 during temperature fluctuation are opposite to each other. By providing the stress relief portion 32, it is possible to relieve the stress acting on the mounting portion (solder joint portion) of the semiconductor package 41, thereby improving the connection reliability.

In FIG. 13, a smile warp occurs in the printed circuit board 30 when the temperature rises. A smile warp occurs in the semiconductor package 41. The semiconductor package 41 is disposed on the second surface 302, and the warping direction is reversed. By providing the stress relief portion 32, it is possible to relieve the stress acting on the mounting portion (solder joint portion) of the semiconductor package 41, thereby improving the connection reliability. In FIG. 13, the heat dissipation gel 60 may be disposed between the semiconductor package 41 and the cover 22 (not shown).

Although Al is used as an example of the material of the case 21 having a linear expansion coefficient greater than that of the printed circuit board 30, the material is not limited to this. For example, resin materials such as PPS and PBT may be used. Although Fe is used as an example of the material of the case 21 having a linear expansion coefficient smaller than that of the printed circuit board 30, the material is not limited to this. For example, ceramics may be used.

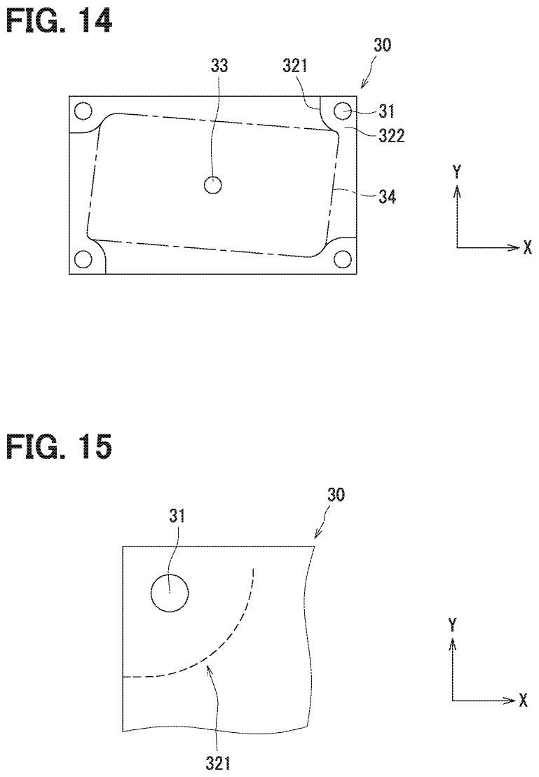

As shown in FIG. 14, a fixing hole 33 may be provided in the printed circuit board 30 to reinforce the fixing of the printed circuit board 30 to the case 21 (fixed structure). The fixing hole 31 corresponds to a first fixing hole, and the fixing hole 33 corresponds to a second fixing hole. By providing the fixing hole 33, the strength of attachment to the case 21 can be increased. The fixing hole 33 is provided in an area 34 surrounded by all the slits 321. The area 34 is a region where the transmission of stress originating from the fixing hole 31 is blocked by the slit 321. The fixing hole 33 is located between the slits 321. In FIG. 14, the fixing hole 33 is provided in the central region of the board. The stress originating from the fixing hole 31 is not transmitted to the fixing hole 33 in the area 34. Therefore, the fixing hole 33 does not need the slit 321, and the fixing hole 33 improves the attachment strength between the printed circuit board 30 and the case 21.

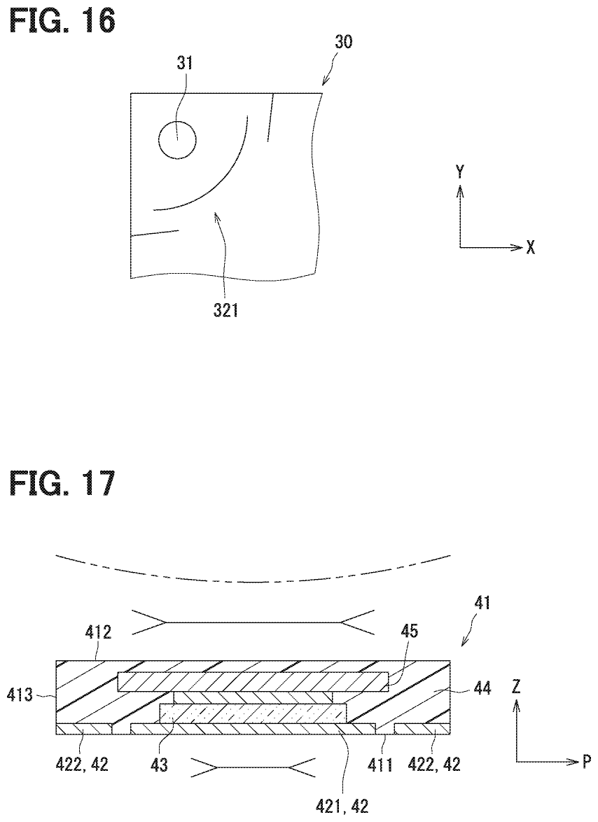

The shape and arrangement of the slit 321 are not limited to the above example. For example, as shown in FIG. 15, a discontinuous slit 321 may be used. The slit 321 is divided into plural parts in the extending direction. Moreover, as shown in FIG. 16, the slit 321 may be arranged in multiple layers. The slit 321 is arranged in multiple rows in the radial direction from the fixing hole 31.

### Second Embodiment

This embodiment is a modification based on the basic form of the preceding embodiment, and the description of the preceding embodiment can be incorporated by reference. In the preceding embodiment, the upper surface of the semiconductor chip in the semiconductor package is covered with the sealing resin body. Alternatively, a semiconductor package having a metal plate disposed on a semiconductor chip may be used.

FIG. 17 is a cross-sectional view showing a semiconductor package in the electronic device according to this embodiment. FIG. 17 corresponds to FIG. 5. FIG. 17, like FIG. 6, shows the relationship of the amount and shape of warp when the temperature drops. The solid line with inward arrows at both ends indicates the magnitude (amount) of contraction. The double chain line indicates the warping shape of the semiconductor package when the temperature drops.

The semiconductor package 41 is a QFN type non-leaded package, similar to the preceding embodiment. The semiconductor package 41 includes the lead frame 42, the semiconductor chip 43, and the sealing resin body 44, similar to the preceding embodiment (see FIG. 5). The semiconductor package 41 of this embodiment further includes a clip 45 which is a metal plate. The sealing resin body 44 seals the clip 45 together with the semiconductor chip 43.

The clip 45 is made of a metal material with good conductivity, such as Cu. The clip 45 is mounted on the semiconductor chip 43. Such a structure is used in power semiconductors that pass large currents, such as power MOS. The semiconductor chip 43 of this embodiment has a MOSFET formed on a semiconductor substrate. MOSFET is an abbreviation for Metal Oxide Semiconductor Field Effect Transistor. In the semiconductor chip 43, a drain electrode is formed on the lower surface facing the lead frame 42, and a source electrode is formed on the upper surface. The clip 45 is soldered to the source electrode.

When the clip 45 is thicker than the lead frame 42 and/or larger than the island 421, the effect of the clip 45 on the semiconductor chip 43 during expansion and contraction will be stronger than the effect of the lead frame 42. For example, when the temperature drops, even if the lead frame 42 and the clip 45 are both made of Cu, the contraction strength of the clip 45 becomes stronger. Therefore, the semiconductor package 41 has a smile warp as shown by the double chain line. When the temperature rises, the semiconductor package 41 develops a cry warp in which the outer periphery is downward.

In the above package structure, Si is interposed between Cu, so that the influence of the semiconductor chip 43 can be offset. When the thickness of the clip 45 is increased, the strength of the clip 45 becomes stronger than that of the lead frame 42, so that deformation occurs toward the clip 45. The strength is proportional to the cube of the thickness.

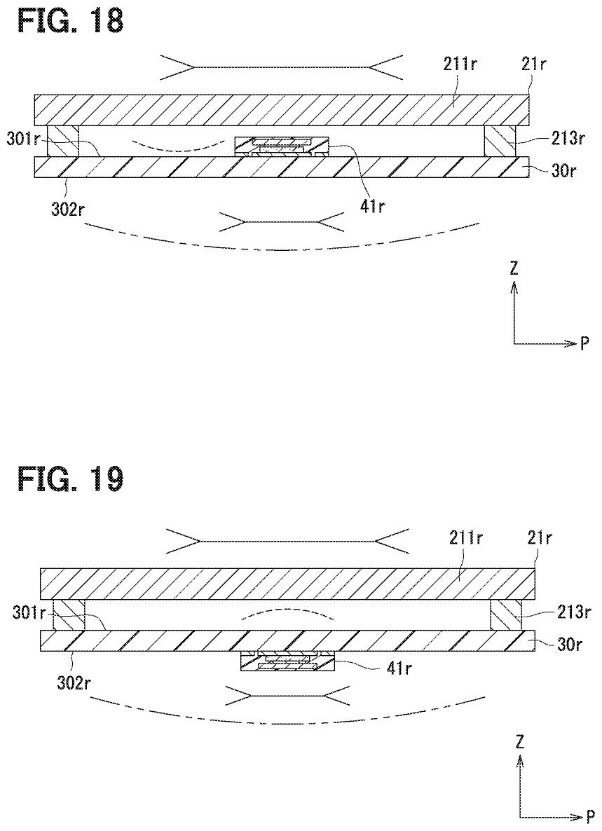

Next, warping of a printed circuit board will be described with reference to FIGS. 18 to 21. Also, the influence of the relationship between the warping of the printed circuit board and the warping of the semiconductor package on the mounting portion of the semiconductor package will be described. FIGS. 18 to 21 show reference examples, and correspond to FIGS. 7 to 10. The reference example differs from this embodiment in that no stress relief portion such as a slit is provided in the printed circuit board. In the reference example, a character “r” is added to the end of the reference numerals of related elements in the present embodiment. The solid line with inward arrows at both ends indicates the magnitude (amount) of contraction. The double chain line indicates the warping shape of the printed circuit board when the temperature drops. The dashed line indicates the warping shape of the semiconductor package when the temperature drops.

In the reference example shown in FIG. 18, the case 21r, which is a fixed structure, is made of Al. When the temperature drops, the case 21r (opposing wall 211r) shrinks significantly in the direction perpendicular to the Z direction. On the other hand, the amount of shrinkage of the printed circuit board 30r is small. The printed circuit board 30r has a smile warp.

The semiconductor package 41r has the same configuration as the semiconductor package 41 shown in FIG. 17. When the temperature drops, the semiconductor package 41r develops a smile warp as shown by the dashed line. The semiconductor package 41r is disposed on the first surface 301r. Therefore, the warping direction of the printed circuit board 30r and the warping direction of the semiconductor package 41r are the same. Therefore, it is possible to prevent sudden deformation stress from being applied to the mounting portion (solder joint portion) of the semiconductor package 41r.

When the temperature rises, the printed circuit board 30r has cry warp, and the semiconductor package 41r has cry warp. The semiconductor package 41r is arranged on the first surface 301r, and the warping direction is the same. Therefore, it is possible to prevent sudden deformation stress from being applied to the mounting portion of the semiconductor package 41r.

In the reference example shown in FIG. 19, the semiconductor package 41r is disposed on the second surface 302r of the printed circuit board 30r. The other configurations are the same as those of the reference example shown in FIG. 18. When the temperature drops, a smile warp occurs in the printed circuit board 30r due to the difference in the linear expansion coefficient between the case 21r and the printed circuit board 30r.

When the temperature drops, the semiconductor package 41r develops a smile warp as shown by the dashed line. The semiconductor package 41r is disposed on the second surface 302r. Therefore, the warping direction of the printed circuit board 30r and the warping direction of the semiconductor package 41r are opposite to each other. Therefore, a sudden deformation stress is applied to the mounting portion (solder joint portion) of the semiconductor package 41r, and the connection reliability of the mounting portion of the semiconductor package 41r is likely to decrease.

When the temperature rises, the printed circuit board 30r undergoes cry warping. The semiconductor package 41r has cry warp. The semiconductor package 41r is disposed on the second surface 302r, and the warping direction is reversed. Therefore, the connection reliability of the mounting portion of the semiconductor package 41r is likely to decrease.

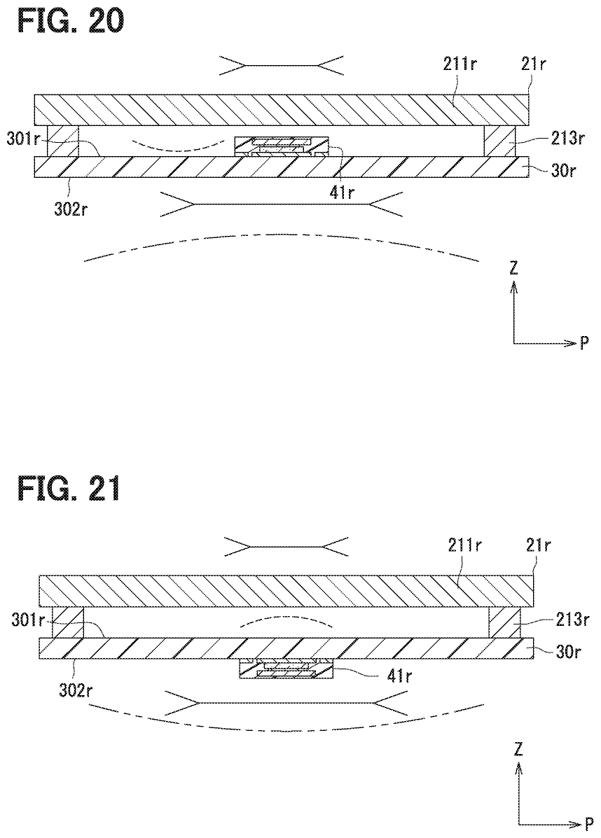

In the reference example shown in FIG. 20, the case 21r, which is a fixed structure, is made of Fe. When the temperature drops, the printed circuit board 30r shrinks significantly in the direction perpendicular to the Z direction. On the other hand, the amount of shrinkage of the case 21r (opposing wall 211r) is small. The printed circuit board 30r has a cry warp.

When the temperature drops, the semiconductor package 41r develops a smile warp as shown by the dashed line. The semiconductor package 41r is disposed on the first surface 301r of the printed circuit board 30r. Therefore, the warping direction of the printed circuit board 30r and the warping direction of the semiconductor package 41r are opposite to each other. Therefore, the connection reliability of the mounting portion of the semiconductor package 41r is likely to decrease.

When the temperature rises, smile warp occurs in the printed circuit board 30r. The semiconductor package 41r has a cry warp. The semiconductor package 41r is disposed on the first surface 301r, and the warping direction is reversed. Therefore, the connection reliability of the mounting portion of the semiconductor package 41r is likely to decrease.

In the reference example shown in FIG. 21, the semiconductor package 41r is disposed on the second surface 302r of the printed circuit board 30r. The other configurations are the same as those of the reference example shown in FIG. 20. When the temperature drops, the difference in the linear expansion coefficient between the case 21r and the printed circuit board 30r causes a cry warp in the printed circuit board 30r. When the temperature drops, the semiconductor package 41r develops a smile warp as shown by the dashed line. Since the semiconductor package 41r is disposed on the second surface 302r, the warping direction of the printed circuit board 30r and the warping direction of the semiconductor package 41r are the same. Therefore, it is possible to prevent sudden deformation stress from being applied to the mounting portion (solder joint portion) of the semiconductor package 41r.

When the temperature rises, smile warp occurs in the printed circuit board 30r. The semiconductor package 41r has a cry warp. The semiconductor package 41r is disposed on the second surface 302r, and the warping direction is the same. Therefore, it is possible to prevent sudden deformation stress from being applied to the mounting portion (solder joint portion) of the semiconductor package 41r.

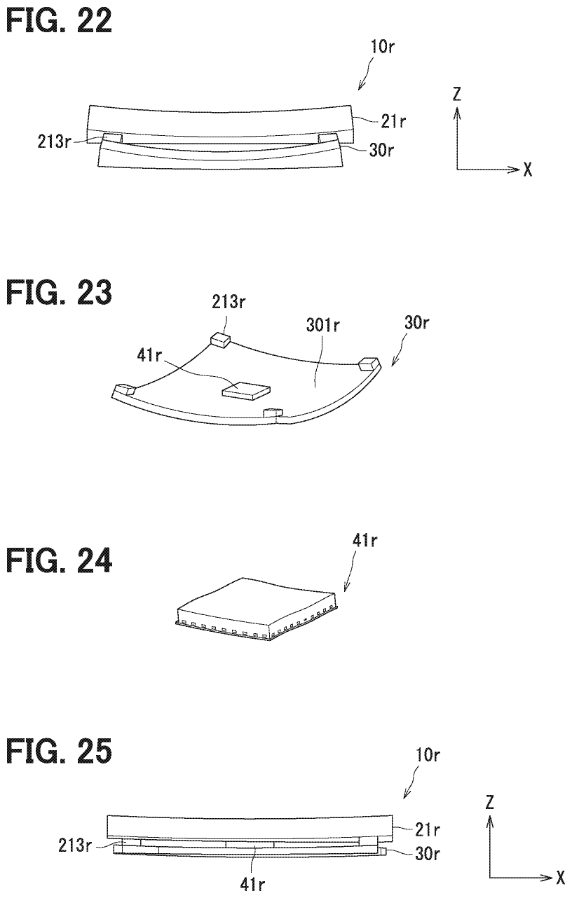

FIGS. 22 to 26 show the results of simulation of deformation due to temperature fluctuations. FIGS. 22, 23, and 24 show the results of simulations in which the temperature is changed to a low temperature in a structural model similar to the reference example shown in FIG. 18. FIG. 22 is a side view of the electronic device as seen in the Y direction. FIG. 23 shows warping of a printed circuit board. FIG. 24 shows warping of a semiconductor package.

In the electronic device 10r, the semiconductor package 41r is disposed on the first surface 301r of the printed circuit board 30r. The case 21r is made of Al. As shown in FIGS. 22 and 23, smile warping occurs in the printed circuit board 30r when the low temperature fluctuates. As shown in FIGS. 23 and 24, a smile warp occurs in the semiconductor package 41r, and the warping direction is the same.

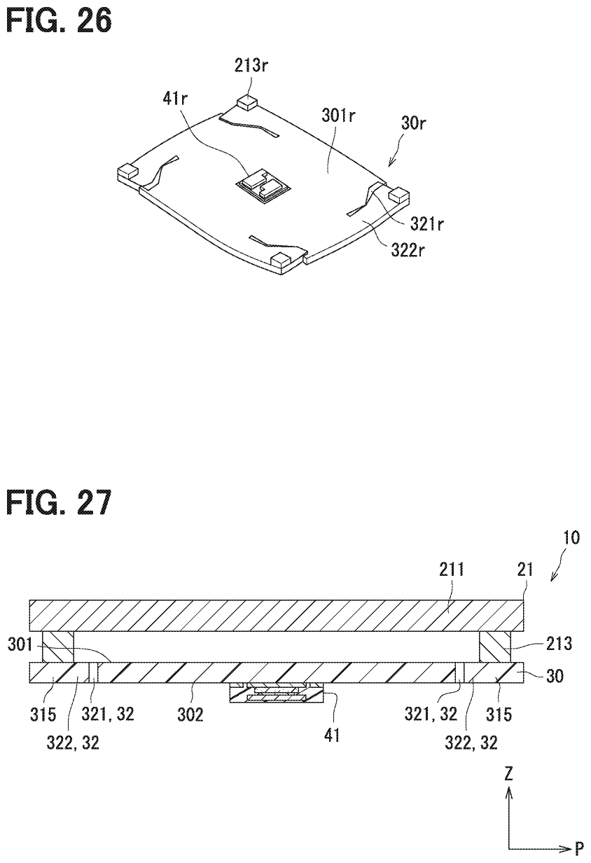

FIGS. 25 and 26 show the results of simulations when the temperature is changed to a low temperature using a structural model in which slits (stress relief portions) are added to the structure shown in FIGS. 22 to 24. FIG. 25 is a side view of the electronic device as seen in the Y direction. FIG. 25 corresponds to FIG. 22. FIG. 26 shows warping of a printed circuit board.

As shown in FIG. 26, the slit 321r and the partition portion 322r are provided at the four corners of the printed circuit board 30r. As shown in FIGS. 25 and 26, the deformation can be absorbed by the slit 321r and the partition portion 322r, even if a displacement is applied to the fixing hole of the printed circuit board 30r.

For the semiconductor package structure shown in FIG. 17, a simulation is carried out to determine the warping characteristics of the printed circuit board when the temperature is decreased from 20 °C to −40 °C. The simulation is performed for three levels: no slit (no stress relief portion), small slit, and large slit, for cases where the warping direction is different between the printed circuit board and the semiconductor package and where the warping directions are the same. Although not shown in the figures, the same results as those in the preceding embodiment (see FIGS. 11 and 12) are obtained.

FIG. 27 shows an example of an electronic device according to this embodiment. FIG. 27 corresponds to FIG. 4. For convenience, FIG. 27 shows only the case, which is a fixed structure, of the housing, and the case is shown in a simplified manner. As the electronic component, only a semiconductor package is shown. Additionally, screw holes, fixing holes, and screws are omitted.

As shown in FIG. 27, the electronic device 10 includes the semiconductor package 41 having the structure shown in FIG. 17. The semiconductor package 41 is disposed on the second surface 302 of the printed circuit board 30. The case 21, which is a fixed structure, is made of Al. The printed circuit board 30 has the stress relief portion 32. The stress relief portion 32 includes the slit 321 and the partition portion 322 as shown in the previous embodiment. The stress relief portion 32 has the same configuration as that shown in the preceding embodiment (see FIGS. 2 and 3). The stress relief portion 32 is provided for each of the fixing portions 315 (fixing holes). In FIG. 27, the heat dissipation gel 60 may be placed between the semiconductor package 41 and the cover 22 (not shown). The other configurations are the same as those shown in the preceding embodiment.

According to the electronic device 10 of the second embodiment, it is possible to achieve the same effects as the electronic device 10 shown in the previous embodiment. For example, in FIG. 27, the linear expansion coefficient of the case 21 which is the fixed structure is greater than the linear expansion coefficient of the printed circuit board 30. For example, when the temperature drops, the printed circuit board 30 develops a smile warp, similar to FIG. 19. The semiconductor package 41 includes the clip 45 (metal plate material) disposed on the semiconductor chip 43. As shown in FIG. 17, smile warp occurs when the temperature drops. The semiconductor package 41 is disposed on the second surface 302 of the printed circuit board 30. When the temperature drops, the warping direction of the printed circuit board 30 and the warping direction of the semiconductor package 41 are opposite to each other.

For example, when the temperature rises, the printed circuit board 30 undergoes cry warp. The semiconductor package 41 has a cry warp. The semiconductor package 41 is disposed on the second surface 302, and the warping direction is reversed.

Since the warping direction is reversed when the temperature changes, the printed circuit board 30 is provided with the stress relief portion 32. The stress relief portion 32 relieves stress acting on the mounting portion (solder joint portion) of the semiconductor package 41 due to different warping directions. Therefore, the connection reliability of the semiconductor package 41 can be improved.

The appearance of the semiconductor package shown in the preceding embodiment (see FIG. 5) and the appearance of the semiconductor package of this embodiment (see FIG. 17) appear to be substantially the same. However, due to the difference in the internal structure, the warping direction becomes reversed when the temperature changes. In this way, warping may be in different directions when the temperature changes while the semiconductor packages 41 appear the same. In this case, based on the knowledge gained, the printed circuit board 30 is provided with the stress relief portion 32 while the warping direction during temperature fluctuations is reversed. The connection reliability of the semiconductor package 41 can be improved due to the stress relief portion.

### Modifications

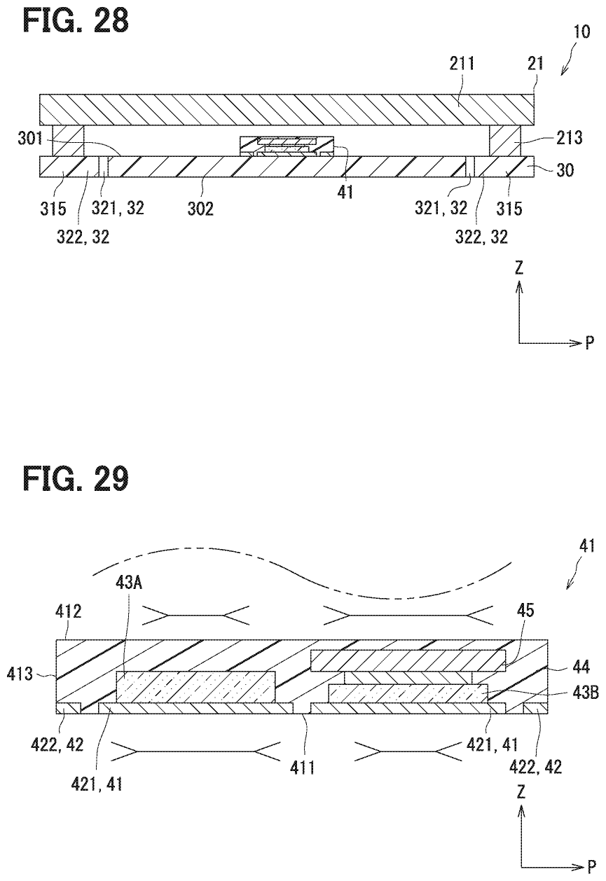

The arrangement of the semiconductor package 41 is not limited to the second surface 302. For example, as shown in FIG. 28, when the semiconductor package 41 is provided on the first surface 301, the stress relief portion 32 may be provided on the printed circuit board 30. In FIG. 28, the case 21 is made of Fe. Therefore, for example, when the temperature drops, the printed circuit board 30 undergoes cry warping. The semiconductor package 41 has a smile warp. Since the semiconductor package 41 is disposed on the first surface 301, the warping direction of the printed circuit board 30 and the warping direction of the semiconductor package 41 during temperature fluctuations are opposite to each other. By providing the stress relief portion 32, it is possible to relieve the stress acting on the mounting portion (solder joint portion) of the semiconductor package 41, thereby improving the connection reliability.

In FIG. 28, smile warp occurs in the printed circuit board 30 when the temperature rises. A cry warp occurs in the semiconductor package 41. The semiconductor package 41 is arranged on the first surface 301, and the warping direction is reversed. By providing the stress relief portion 32, it is possible to relieve the stress on the mounting portion (solder joint portion) of the semiconductor package 41, thereby improving the connection reliability. In FIG. 28, the heat dissipation gel 60 may be placed between the semiconductor package 41 and the case 21.

### Third Embodiment

A third embodiment is a modification based on the basic form of the preceding embodiment, and the description of the preceding embodiment can be incorporated by reference. In the previous embodiment, the semiconductor package included only one semiconductor chip. Alternatively, a multi-chip package may be used as the semiconductor package.

FIG. 29 is a cross-sectional view showing a semiconductor package in the electronic device according to this embodiment. FIG. 29 corresponds to FIG. 17. FIG. 29 shows the amount of shrinkage and the warping direction when the temperature drops, similar to FIG. 17. The solid line with inward arrows at both ends indicates the magnitude (amount) of contraction. The double chain line indicates the warp shape of the semiconductor package when the temperature drops.

The semiconductor package 41 shown in FIG. 29 is a QFN non-leaded package, similar to the preceding embodiment. The semiconductor package 41 has a structure in which the configuration shown in FIG. 5 and the configuration shown in FIG. 17 are arranged side by side in a common (single) package. The semiconductor package 41 includes the lead frame 42, the semiconductor chip 43A, the semiconductor chip 43B, the sealing resin body 44, and the clip 45. The semiconductor chip 43B has a power MOSFET formed thereon that drives a large current. The semiconductor chip 43A is formed with a control IC that controls the driving of the MOSFET of the semiconductor chip 43B. The semiconductor package 41 may be called an IPD.

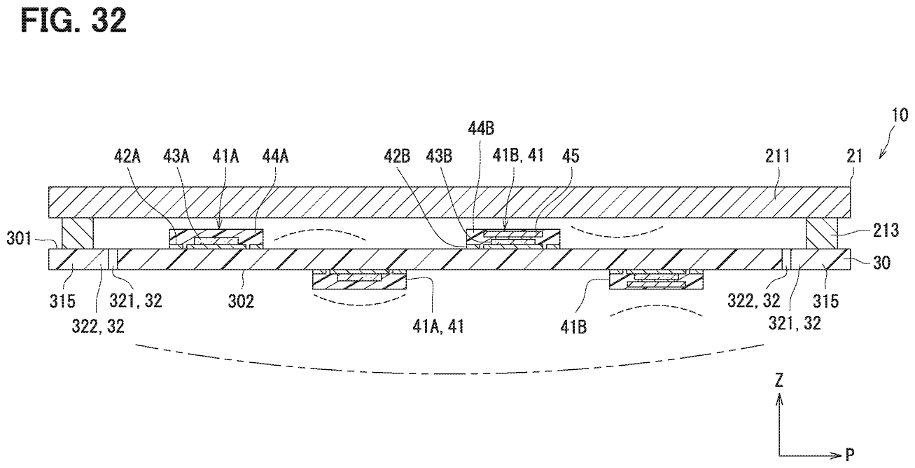

The semiconductor chip 43A corresponds to the semiconductor chip 43 shown in FIG. 5. The semiconductor chip 43A is disposed on one of the islands 421 of the lead frame 42. A pad (not shown) is formed on the upper surface of the semiconductor chip 43A, and electrically connected to the terminal 422 via bonding wire. The upper surface of the semiconductor chip 43A is covered with the sealing resin body 44. The semiconductor chip 43B corresponds to the semiconductor chip 43 shown in FIG. 17. The clip 45 is bonded to the upper surface of the semiconductor chip 43B. In FIG. 32, the semiconductor chip 43B is arranged on the island 421 different from the semiconductor chip 43A. Alternatively, the semiconductor chips 43A and 43B may be arranged on the common (single) island 421.

In the stacked portion including the semiconductor chip 43A, the linear expansion coefficient of Cu constituting the lead frame 42 is greater than the linear expansion coefficient of Si constituting the semiconductor chip 43. Therefore, when the temperature drops, the lead frame 42 shrinks significantly, causing a cry warp. In the stacked portion including the semiconductor chip 43B, the clip 45 is thicker than the lead frame 42 and/or larger than the island 421. Therefore, when the temperature drops, even if the lead frame 42 and the clip 45 are both made of Cu, the contraction strength of the clip 45 increases. As a result, a smile warp occurs in which the outer periphery is upward. Both of the cry warp and the smile warp are generated in the single semiconductor package 41.

The same is true when the temperature rises. When the temperature rises, smile warp occurs in the stacked portion of the semiconductor chip 43A, and cry warp occurs in the stacked portion of the semiconductor chip 43B. Cry warp and smile warp appear in the single semiconductor package 41.

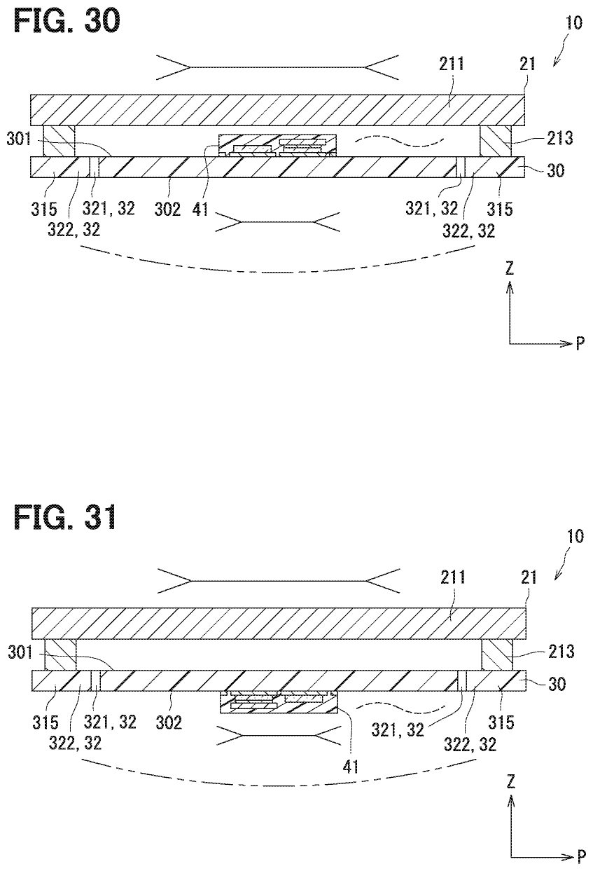

FIG. 30 shows an electronic device according to this embodiment. FIG. 30 corresponds to FIG. 4. For convenience, FIG. 30 shows only the case, which is a fixed structure, of the housing, and the case is shown in a simplified manner. As the electronic component, only a semiconductor package is shown. Additionally, screw holes, fixing holes, screws, and heat dissipation gel are omitted.

As shown in FIG. 30, the electronic device 10 includes the semiconductor package 41 having the structure shown in FIG. 29. The semiconductor package 41 is disposed on the first surface 301 of the printed circuit board 30. The case 21, which is a fixed structure, is made of Al. The printed circuit board 30 has the stress relief portion 32. The stress relief portion 32 includes, for example, the slit 321 and the partition portion 322. The stress relief portion 32 has the same configuration as that shown in the preceding embodiment (see FIGS. 2 and 3). The stress relief portion 32 is provided for each of the fixing portions 315 (fixing holes).

FIG. 31 shows another example of an electronic device. In FIG. 31, the semiconductor package 41 is disposed on the second surface 302 of the printed circuit board 30. The other configurations are the same as those shown in the example of FIG. 30.

As shown in the third embodiment, the semiconductor package 41 may be a multi-chip package. The multi-chip package has the semiconductor chip 43A on the top surface of which no clip 45 is arranged, and the semiconductor chip 43B on the top surface of which the clip 45 (metal plate material) is arranged. In such a configuration, as shown in FIG. 29, cry warp and smile warp appear in the single semiconductor package 41 when the temperature fluctuates. Therefore, as shown in FIGS. 30 and 31, whether the semiconductor package 41 is mounted on the first surface 301 or the second surface 302, the semiconductor package 41 has a warped portion that is opposite to the warping of the printed circuit board 30. By providing the stress relief portion 32 regardless of the mounting surface, it is possible to relieve the stress acting on the mounting portion of the semiconductor package 41 due to the warp in the opposite direction.

When the stress relief portion 32 is not provided, the connection reliability of the mounting portion of the stacked portion including the semiconductor chip 43A and the stacked portion including the semiconductor chip 43B, which are warped in the opposite direction to the warp of the printed circuit board 30, will be reduced. In other words, the solder life is reduced. This also reduces the product lifespan. By providing the stress relief portion 32, the solder life of the portion curved in the opposite direction can be improved, and the product life can be improved as well.

The electronic device is not limited to the configuration shown in FIGS. 30 and 31. The case 21 may have a smaller linear expansion coefficient than the printed circuit board 30. In this case, whether the semiconductor package 41 is mounted on the first surface 301 or the second surface 302, the semiconductor package 41 has a warped portion that is opposite to the warping of the printed circuit board 30. Therefore, by providing the stress relief portion 32 regardless of the mounting surface, it is possible to relieve the stress acting on the mounting portion of the semiconductor package 41 due to the warp in the opposite direction.

### Fourth Embodiment

A fourth embodiment is a modification based on the basic form of the preceding embodiment, and the description of the preceding embodiment can be incorporated by reference. The previous embodiment included a single semiconductor package. Alternatively, multiple types of semiconductor packages are mounted on a common surface.

FIG. 32 shows an electronic device according to this embodiment. FIG. 32 corresponds to FIG. 4. For convenience, FIG. 32 shows only the case, which is a fixed structure, of the housing, and the case is shown in a simplified manner. As the electronic component, only a semiconductor package is shown. Additionally, screw holes, fixing holes, screws, and heat dissipation gel are omitted. The dashed line in FIG. 32 indicates the warping shape of the semiconductor package when the temperature drops. The double chain line indicates the warping shape of the printed circuit board when the temperature drops.

As shown in FIG. 32, the electronic device 10 includes the semiconductor package 41A having a configuration similar to that shown in FIG. 5, and the semiconductor package 41B having a configuration similar to that shown in FIG. 17. The semiconductor package 41A corresponds to a first semiconductor package, and the semiconductor package 41B corresponds to a second semiconductor package. The semiconductor package 41A includes the lead frame 42A, the semiconductor chip 43A, and the sealing resin body 44A. The lead frame 42A corresponds to a first lead frame, and the semiconductor chip 43A corresponds to a first semiconductor chip. The sealing resin body 44A corresponds to a first sealing resin body. The semiconductor package 41B includes the lead frame 42B, the semiconductor chip 43B, the sealing resin body 44A, and the clip 45. The lead frame 42B corresponds to a second lead frame, and the semiconductor chip 43B corresponds to a second semiconductor chip. The sealing resin body 44B corresponds to a second sealing resin body.

The semiconductor packages 41A and 41B are arranged on a common surface of the printed circuit board 30. In FIG. 32, the semiconductor packages 41A and 41B are arranged on the first surface 301. The semiconductor packages 41A and 41B are arranged on the second surface 302. The case 21, which is a fixed structure, is made of, for example, Al. The printed circuit board 30 has the stress relief portion 32. The stress relief portion 32 includes, for example, the slit 321 and the partition portion 322. The stress relief portion 32 has the same configuration as that shown in the preceding embodiment (see FIGS. 2 and 3). The stress relief portion 32 is provided for each of the fixing portions 315 (fixing holes).

As shown in this embodiment, the semiconductor package 41A (first semiconductor package) and the semiconductor package 41B (second semiconductor package) are arranged on a common surface of the printed circuit board 30. When the temperature fluctuates, one of the semiconductor packages 41A and 41B develops a cry warp, and the other develops a smile warp. Regardless of whether the semiconductor packages 41A and 41B are mounted on the first surface 301 or the second surface 302, the warping direction of one of the semiconductor packages 41A and 41B is opposite to the warping direction of the printed circuit board 30. Therefore, by providing the stress relief portion 32 regardless of the mounting surface, it is possible to relieve the stress acting on the mounting portion of the semiconductor package 41 due to the warp in the opposite direction.

In FIG. 32, when the temperature drops, smile warp occurs in the printed circuit board 30. Cry warp occurs in the semiconductor package 41A, and smile warp occurs in the semiconductor package 41B. Therefore, of the semiconductor packages 41A and 41B arranged on the first surface 301, the warping direction of the semiconductor package 41A and the warping direction of the printed circuit board 30 are opposite to each other. Of the semiconductor packages 41A and 41B arranged on the second surface 302, the warping direction of the semiconductor package 41B and the warping direction of the printed circuit board 30 are opposite to each other. Therefore, the semiconductor package 41A arranged on the first surface 301 and the semiconductor package 41B arranged on the second surface 302 correspond to the semiconductor packages 41 in which stress acts on the mounting portion due to the different warping directions. By providing the stress relief portion 32, the connection reliability between the semiconductor package 41A arranged on the first surface 301 and the semiconductor package 41B arranged on the second surface 302 can be improved. As with multi-chip packages, product life can be improved.

The electronic device is not limited to the configuration shown in FIG. 32. The semiconductor packages 41A and 41B may be arranged on only the first surface 301 or only the second surface 302. The case 21 may have a smaller linear expansion coefficient than the printed circuit board 30. In this case, in FIG. 32, the semiconductor package 41B arranged on the first surface 301 and the semiconductor package 41A arranged on the second surface 302 correspond to the semiconductor packages 41 in which stress acts on the mounting portion due to the different warping directions. By providing the stress relief portion 32 regardless of the mounting surface, it is possible to relieve the stress acting on the mounting portion of the semiconductor package 41 due to the warping in the opposite direction.

### Fifth Embodiment

A fifth embodiment is a modification based on the basic form of the preceding embodiment, and the description of the preceding embodiment can be incorporated by reference. In the previous embodiment, the slit and the partition portion are provided as the stress relief portion. Alternatively, groove and thin portion may be provided.

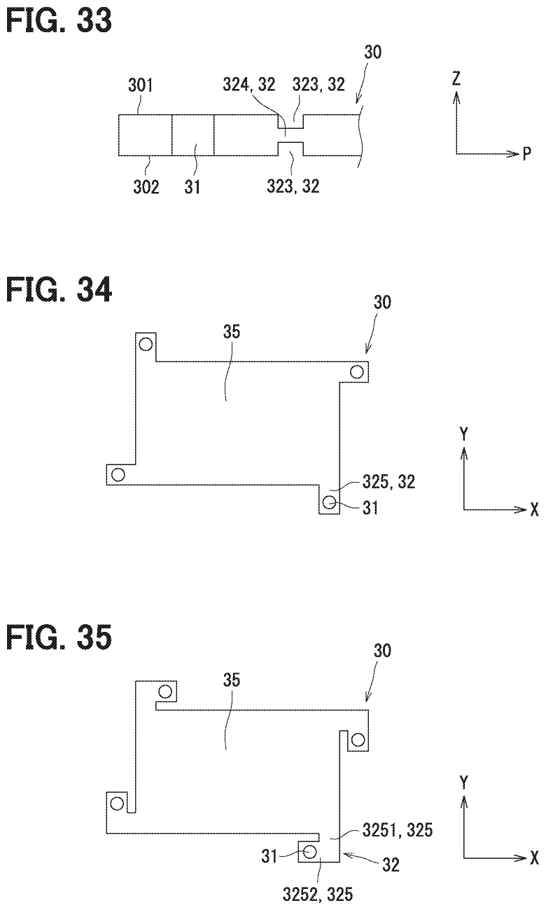

FIG. 33 is a cross-sectional view showing a part of a printed circuit board in the electronic device according to this embodiment. FIG. 33 shows the area around the fixing hole and the stress relief portion. The printed circuit board 30 shown in FIG. 33 has the stress relief portion 32 provided corresponding to the fixing hole 31, similar to the preceding embodiment. The stress relief portion 32 is provided for each of the fixing holes 31. The stress relief portion 32 includes the groove 323 and the thin portion 324.

The groove 323 is a blind hole extending in a predetermined direction. The groove 323 may be open in the first surface 301 or the second surface 302. In FIG. 33, the groove 323 on the first surface 301 and the groove 323 on the second surface 302 are provided to overlap along the extension direction.

The thin portion 324 is made thinner by the groove 323 than the surrounding area of the groove 323. The thin portion 324 is provided adjacent to the groove 323 in the Z direction. In FIG. 33, the thin portion 324 is defined between the groove 323 on the first surface 301 and the groove 323 on the second surface 302. The thin portion 324 connects the side of the groove 323 adjacent to the fixing hole 31 to the opposite side of the fixing hole 31 via the groove 323. When stress is applied, the thin portion 324 undergoes elastic deformation (spring deformation). The groove 323 does not penetrate the printed circuit board 30. For example, the groove 323 for the fixing hole 311 may have one end open in the side surface 303 and the other end open in the side surface 304. The other configurations are the same as those shown in the preceding embodiment.

As shown in this embodiment, the stress relief portion 32 may include a portion that relieves stress by elastic deformation. By elastically deforming (spring deformation), it is possible to effectively relieve the stress acting on the mounting portion of the semiconductor package 41 due to the warping in the opposite direction.

The stress relief portion 32 may include the groove 323 and the thin portion 324 adjacent to the groove 323 in the Z direction. The groove 323 can limit the range of stress transmission. The thin portion 324 adjacent to the groove 323 is elastically deformed by application of stress. The elastic deformation of the thin portion 324 can relieve stress.

The stress relief portion 32 including the slit 321 and the partition portion 322 shown in the previous embodiment may be replaced with the stress relief portion 32 including the groove 323 and the thin portion 324 shown in this embodiment.

### Sixth Embodiment

A sixth embodiment is a modification based on the basic form of the preceding embodiment, and the description of the preceding embodiment can be incorporated by reference. In the preceding embodiment, the stress relief portion includes the slit or the groove. Alternatively, an extension portion extending from the main body may be provided.

FIG. 34 is a cross-sectional view showing a part of a printed circuit board in the electronic device according to this embodiment. The printed circuit board 30 shown in FIG. 34 has the stress relief portion 32 corresponding to the fixing hole 31, similar to the preceding embodiment. The stress relief portion 32 is provided for each of the fixing holes 31. The stress relief portion 32 includes an extension portion 325 that is continuous with the main body 35.

The main body 35 is the main part of the printed circuit board 30. Conductors such as wiring layers are arranged on the main body 35, and electronic components 40 including the semiconductor package 41 are mounted thereon. The printed circuit board 30 has four extension portions 325. The extension portion 325 is provided with the fixing hole 31. The extension portion 325 extends from the main body 35 toward the fixed position with the case 21. The extension portion 325 shown in FIG. 34 extends in one direction. The extension portion 325 extends in the X direction or the Y direction. When stress is applied, the extension portion 325 undergoes elastic deformation (spring deformation). The other configurations are the same as those shown in the preceding embodiment.

As shown in this embodiment, the stress relief portion 32 may include a portion that relieves stress by elastic deformation. By elastically deforming (spring deformation), it is possible to effectively relieve the stress acting on the mounting portion of the semiconductor package 41 due to the warping in the opposite direction.

The stress relief portion 32 may include the extension portion 325 that extends from the main body 35 and has the fixing hole 31 provided therein. The extension portion 325 is elastically deformed when stress is applied. The elastic deformation of the extension portion 325 can relieve stress.

### Modifications

The shape of the extension portion 325 is not limited to the example described above. For example, as shown in FIG. 35, the extension portion 325 may include a first extension portion 3251 and a second extension portion 3252. The first extension portion 3251 extends in a predetermined direction. The second extension portion 3252 is continuous with the first extension portion 3251 and extends in a direction different from the predetermined direction. In FIG. 35, one end of the first extension portion 3251 is connected to the main body 35, and the other end is connected to the second extension portion 3252. For example, the first extension portion 3251 extends in the X direction, and the second extension portion 3252 extends in the Y direction. The first extension portion 3251 extends in the Y direction, and the second extension portion 3252 extends in the X direction. The first extension portion 3251 extends in a direction perpendicular to the side surface of the printed circuit board 30 (main body 35). The second extension portion 3252 extends along the side surface of the printed circuit board 30. The extension portion 325 has a generally L-shape in a plan view. According to the configuration shown in FIG. 35, the length from the fixing hole 31 to the main body 35 is long, and the extension portion 325 is more likely to be elastically deformed. In addition, it is possible to suppress an increase in physique.

The stress relief portion 32 including the slit 321 and the partition portion 322 shown in the previous embodiment may be replaced with the stress relief portion 32 including the extension portion 325 shown in this embodiment.

### Other Embodiments

The disclosure in this description, the drawings, and the like is not limited to the exemplified embodiments. The disclosure includes exemplary embodiments and modifications by those skilled in the art based on the exemplary embodiments. For example, the disclosure is not limited to the combinations of components and/or elements shown in the embodiments. The disclosure may be implemented in various combinations. The disclosure may include additional portions that can be added to the embodiments. The disclosure includes those in which the components and/or elements of the embodiments are omitted. The disclosure includes the replacement or combination of components and/or elements between one embodiment and another embodiment. The disclosed technical scope is not limited to the description of the embodiments. It should be understood that some disclosed technical ranges are indicated by description of claims, and includes every modification within the equivalent meaning and the scope of description of claims.

The disclosure in the specification, drawings and the like is not limited by the description of the claims. The disclosures in the description, the drawings, and the like encompass the technical ideas described in the claims, and further extend to a wider variety of technical ideas than those in the claims. Thus, various technical ideas can be extracted from the disclosure of the specification, the drawings and the like without being limited to the description of the present disclosure.

When an element or a layer is described as “disposed above” or “connected”, the element or the layer may be directly disposed above or connected to another element or another layer, or an intervening element or an intervening layer may be present therebetween. In contrast, when an element or a layer is described as “disposed directly above” or “directly connected”, an intervening element or an intervening layer is not present. Other terms used to describe the relationships between elements (for example, “between” vs. “directly between”, and “adjacent” vs. “directly adjacent”) should be interpreted similarly. As used herein, the term “and/or” includes any combination and all combinations relating to one or more of the related listed items. For example, the term A and/or B includes only A, only B, or both A and B. The description of A and/or B means at least one of A and B.

Spatial relative terms “inside”, “outside”, “back”, “bottom”, “low”, “top”, “high”, etc. are used herein to facilitate the description that describes relationships between one element or feature and another element or feature. Spatial relative terms can be intended to include different orientations of a device in use or operation, in addition to the orientations depicted in the drawings. For example, when the device in the figure is flipped over, an element described as “below” or “directly below” another element or feature is directed “above” the other element or feature. Therefore, the term “below” can include both above and below. The device may be oriented in the other direction (rotated 90 degrees or in any other direction) and the spatially relative terms used herein are interpreted accordingly.

What is claimed is:

1. An electronic device comprising:
a printed circuit board having a first surface and a second surface opposite to each other in a thickness direction of the printed circuit board;
a semiconductor package mounted on the printed circuit board; and
a fixed structure having a portion facing the first surface, wherein the printed circuit board has a plurality of fixing holes to fix the printed circuit board to the fixed structure,
a warping direction of the printed circuit board and a warping direction of the semiconductor package are opposite to each other, during temperature fluctuation, in the thickness direction, and
the printed circuit board has a stress relief portion to relieve stress on a mounting portion of the semiconductor package due to difference in warping direction.

2. The electronic device according to claim 1, wherein the semiconductor package is a non-leaded package.

3. The electronic device according to claim 2, wherein the stress relief portion is provided around the fixing hole.

4. The electronic device according to claim 3, wherein a part of the stress relief portion is configured to relieve the stress by elastic deformation.

5. The electronic device according to claim 4, wherein
the stress relief portion has:
a slit provided for each of the fixing holes and passing through the printed circuit board in the thickness direction, and
a partition portion partitioned by the slit and having the fixing hole.

6. The electronic device according to claim 5, wherein the slit is arranged to cross at least one of a plurality of imaginary straight lines imaginary connecting the fixing holes different from each other in a plan view of the thickness direction.

7. The electronic device according to claim 6, wherein at least one slit is located to cross all of the imaginary straight lines.

8. The electronic device according to claim 5, wherein the slit is open in a side surface of the printed circuit board.

9. The electronic device according to claim 8, wherein
the printed circuit board has a rectangular shape in a plan view of the thickness direction, and
the slit is open in a first side surface of the printed circuit board and extends from the first side surface toward a second side surface of the printed circuit board located opposite the first side surface.

10. The electronic device according to claim 5, wherein
each of the plurality of fixing holes is a first fixing hole,
the printed circuit board has a second fixing hole provided separately from the first fixing hole, to reinforce a fixing of the printed circuit board to the fixed structure, and
the second fixing hole is provided in an area surrounded by all of the slits.

11. The electronic device according to claim 4, wherein the stress relief portion has a groove and a thin portion adjacent to the groove in the thickness direction to connect a side of the groove adjacent to the fixing hole to an opposite side of the groove.

12. The electronic device according to claim 4, wherein
the printed circuit board has a main body and an extension portion extending from the main body and having the fixing hole, and
the stress relief portion includes the extension portion.

13. The electronic device according to claim 12, wherein
the extension portion has
a first extension portion extending in a predetermined direction, and
a second extension portion connected to the first extension portion and extending in a direction different from the predetermined direction.

14. The electronic device according to claim 1, wherein
the semiconductor package includes
a lead frame,
a semiconductor chip having a lower surface and an upper surface and arranged on the lead frame so that the lower surface faces the lead frame, and
a sealing resin body in contact with the upper surface of the semiconductor chip to seal,
a coefficient of linear expansion of the fixed structure is greater than that of the printed circuit board, and
the semiconductor package is mounted on the first surface.

15. The electronic device according to claim 1, wherein
the semiconductor package includes
a lead frame,
a semiconductor chip having a lower surface and an upper surface and arranged on the lead frame so that the lower surface faces the lead frame, and
a sealing resin body in contact with the upper surface of the semiconductor chip to seal,
a coefficient of linear expansion of the fixed structure is smaller than that of the printed circuit board, and
the semiconductor package is mounted on the second surface.

16. The electronic device according to claim 1, wherein
the semiconductor package includes
a lead frame,
a semiconductor chip arranged on the lead frame,
a metal plate arranged on the semiconductor chip, and
a sealing resin body sealing the semiconductor chip and the metal plate,
a coefficient of linear expansion of the fixed structure is greater than that of the printed circuit board, and
the semiconductor package is mounted on the second surface.

17. The electronic device according to claim 1, wherein
the semiconductor package includes
a lead frame,
a semiconductor chip arranged on the lead frame,
a metal plate arranged on the semiconductor chip, and
a sealing resin body sealing the semiconductor chip and the metal plate,
a coefficient of linear expansion of the fixed structure is smaller than that of the printed circuit board, and
the semiconductor package is mounted on the first surface.

18. The electronic device according to claim 1, wherein
the semiconductor package is a multi-chip package, and
the semiconductor package includes
a lead frame,
a first semiconductor chip arranged on the lead frame,
a second semiconductor chip arranged on the lead frame,
a metal plate arranged on the second semiconductor chip, and
a sealing resin body sealing the first semiconductor chip, the second semiconductor chip, and the metal plate.

19. The electronic device according to claim 1, further comprising:
the semiconductor package includes a first semiconductor package and a second semiconductor package,
the first semiconductor package has: a first lead frame; a first semiconductor chip having a lower surface and an upper surface and arranged on the first lead frame so that the lower surface faces the first lead frame; and a first sealing resin body in contact with the upper surface of the first semiconductor chip to seal,
the second semiconductor package has: a second lead frame; a second semiconductor chip arranged on the second lead frame; a metal plate arranged on the second semiconductor chip; and a second sealing resin body sealing the second semiconductor chip and the metal plate,
the first semiconductor package and the second semiconductor package are mounted on a common surface of the printed circuit board, and
one of the first semiconductor package and the second semiconductor package has a warping direction, during temperature fluctuation, opposite to a warping direction of the printed circuit board.
